(19) United States
(12) Patent Application Publication
(10) Pub. No.: US 2024/0053679 A1
(43) Pub. Date: Feb. 15, 2024

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM Corporation, Tokyo (JP)

(72) Inventors: Takamitsu TOMIGA, Haibara-gun (JP); Sou KAMIMURA, Haibara-gun (JP); Yoichi NISHIDA, Haibara-gun (JP); Hideaki TSUBAKI, Haibara-gun (JP)

(73) Assignee: FUJIFILM Corporation, Tokyo (JP)

(21) Appl. No.: 18/362,376

(22) Filed: Jul. 31, 2023

(30) Foreign Application Priority Data
Aug. 1, 2022 (JP) 2022-122920
Mar. 17, 2023 (JP) 2023-043552

(51) Int. Cl. G03F 7/039; G03F 7/004; G03F 7/20

(52) U.S. Cl. CPC G03F 7/039; G03F 7/0045; G03F 7/0048; G03F 7/2006

(57) ABSTRACT

An actinic ray-sensitive or radiation-sensitive resin composition including a resin (A) undergoing an increase in alkali solubility due to action of acid; a compound (C) generating acid upon irradiation with an actinic ray or radiation; and a solvent (S) including a solvent SA having a boiling point of 130° C. to 150° C. and a solvent SB having a boiling point of 155° C. to 250° C., in which a content of the solvent SA is higher than a content of the solvent SB, the content of the solvent SB relative to the whole solvent is 1% to 30% by mass, and a concentration of solid contents is 10% by mass or more.

### CROSS-REFERENCE TO RELATED APPLICATIONS

The present application claims priority under 35 U.S.C. § 119 to Japanese Patent Application No. 2022-122920, filed on Aug. 1, 2022, and Japanese Patent Application No. 2023-043552, filed on Mar. 17, 2023. The above applications are hereby expressly incorporated by reference, in their entirety, into the present application.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device.

### 2. Description of the Related Art

In a process for manufacturing semiconductor devices such as integrated circuits (IC) and large-scale integrated circuits (LSI), lithographic microfabrication using an actinic ray-sensitive or radiation-sensitive resin composition is performed.

An example of the lithography method is a method including forming a resist film using an actinic ray-sensitive or radiation-sensitive resin composition, subsequently exposing the obtained resist film, and subsequently performing development to form a resist pattern.

A known actinic ray-sensitive or radiation-sensitive resin composition is a composition that contains a resin (acid-decomposable resin) including a repeating unit having an acid-decomposable group.

In recent years, an actinic ray-sensitive or radiation-sensitive resin composition suitable for pattern formation using a thick resist film has also been proposed (see, for example, JP2020-173341A and JP7001147B). JP2020-173341A and JP7001147B disclose an actinic ray-sensitive or radiation-sensitive resin composition containing two or more solvents.

### SUMMARY OF THE INVENTION

[Reserved]

However, as a result of studies conducted by the inventors of the present invention, it has been found that there is room for further improvement in an exposure latitude (EL) performance.

An object of the present invention is to provide an actinic ray-sensitive or radiation-sensitive resin composition having a good exposure latitude performance, and an actinic ray-sensitive or radiation-sensitive film, a pattern forming method, and a method for producing an electronic device using the actinic ray-sensitive or radiation-sensitive resin composition.

The inventors of the present invention have found that the following configurations enable achievement of the above-described object.

[1]

An actinic ray-sensitive or radiation-sensitive resin composition including:
a resin (A) undergoing an increase in alkali solubility due to action of acid;
a compound (C) generating acid upon irradiation with an actinic ray or radiation; and
a solvent (S) including a solvent SA having a boiling point of 130° C. to 150° C. and a solvent SB having a boiling point of 155° C. to 250° C.,
wherein a content of the solvent SA is higher than a content of the solvent SB, the content of the solvent SB relative to the whole solvent is 1% to 30% by mass, and
a concentration of solid contents is 10% by mass or more.
   [2]

The actinic ray-sensitive or radiation-sensitive resin composition according to [1], wherein the resin (A) is a resin containing a repeating unit having an acid-decomposable group and a repeating unit having a phenolic hydroxy group.

[3]

The actinic ray-sensitive or radiation-sensitive resin composition according to [1] or [2], wherein the resin (A) is a resin containing a repeating unit represented by the following general formula (Ia), a repeating unit represented by the following general formula (IIa), and a repeating unit represented by the following general formula (IIIa).

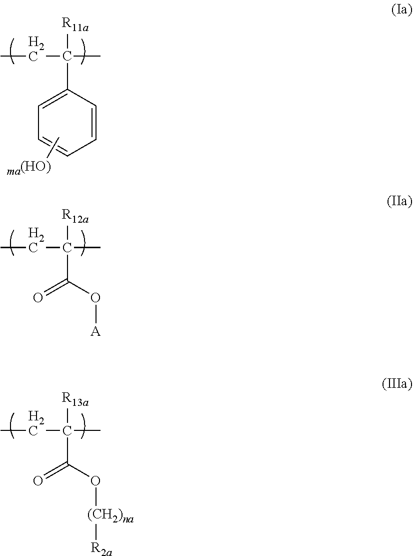

In the general formulae (Ia) to (IIIa),
A represents a group that leaves due to action of acid.
R₁₁ₐ to R₁₃ₐ each independently represent hydrogen or a methyl group.
R₂ₐ represents a cyclic group.
ma represents 1 or 2.
na represents an integer of 0 to 2.
   [4]

The actinic ray-sensitive or radiation-sensitive resin composition according to any one of [1] to [3], wherein the solvent SB has a boiling point of 180° C. to 220° C.

[5]

The actinic ray-sensitive or radiation-sensitive resin composition according to any one of [1] to [4], wherein the solvent SB includes at least one solvent selected from the group consisting of alcohol-based, glycol ether-based, and ester-based solvents.

[6]

The actinic ray-sensitive or radiation-sensitive resin composition according to any one of [1] to [5], wherein the solvent SB includes at least one solvent selected from the group consisting of ethylene glycol, propylene glycol, gamma-butyrolactone, ethyl acetoacetate, dipropylene glycol monomethyl ether, ethylene glycol monobutyl ether acetate, and diethylene glycol diethyl ether.

[7]

The actinic ray-sensitive or radiation-sensitive resin composition according to any one of [1] to [6], wherein the compound (C) generating acid upon irradiation with an actinic ray or radiation is included in an amount of 5% by mass or more relative to a total solid content in the actinic ray-sensitive or radiation-sensitive resin composition.

[8]

The actinic ray-sensitive or radiation-sensitive resin composition according to any one of [1] to [7], wherein a mass ratio of the solvent SB to the compound (C) that generating acid upon irradiation with an actinic ray or radiation (solvent SB/compound (C) that generating acid upon irradiation with actinic ray or radiation) is 0.1 to 200.

[9]

The actinic ray-sensitive or radiation-sensitive resin composition according to any one of [1] to [8], wherein the solvent (S) further includes a solvent SC having a boiling point of 50° C. to 129° C.

[10]

The actinic ray-sensitive or radiation-sensitive resin composition according to any one of [1] to [9], the composition further including a vinyl group-containing compound.

[11]

An actinic ray-sensitive or radiation-sensitive film formed from the actinic ray-sensitive or radiation-sensitive resin composition according to any one of [1] to [10].

[12]

A pattern forming method having:
a step of forming an actinic ray-sensitive or radiation-sensitive film using the actinic ray-sensitive or radiation-sensitive resin composition according to any one of [1] to [10] on a substrate;
a step of exposing the actinic ray-sensitive or radiation-sensitive film to obtain an exposed actinic ray-sensitive or radiation-sensitive film; and
a step of developing the exposed actinic ray-sensitive or radiation-sensitive film using a developer to form a pattern.
   [13]

The pattern forming method according to [12], wherein a light source for the exposing is KrF.

[14]

The pattern forming method according to [12] or [13], wherein the actinic ray-sensitive or radiation-sensitive film formed on the substrate has a film thickness of 500 nm or more.

[15]

A method for producing an electronic device, the method including the pattern forming method according to any one of [12] to [14].

The present invention can provide an actinic ray-sensitive or radiation-sensitive resin composition having a good exposure latitude performance, and an actinic ray-sensitive or radiation-sensitive film, a pattern forming method, and a method for producing an electronic device using the actinic ray-sensitive or radiation-sensitive resin composition.

### DESCRIPTION OF THE PREFERRED EMBODIMENTS

Hereinafter, examples of embodiments for carrying out the present invention will be described.

In the present specification, a range of numerical values expressed with “to” means a range that includes a numerical value before “to” as a lower limit value and a numerical value after “to” as an upper limit value.

In the expression of groups (atomic groups) in the present specification, an expression without the term of substituted or unsubstituted encompasses, in addition to groups having no substituents, groups having substituents. For example, “alkyl group” encompasses not only an alkyl group having no substituent (unsubstituted alkyl group) but also alkyl groups having substituents (substituted alkyl groups). In the present specification, “organic group” refers to a group including at least one carbon atom.

In the present specification, in the case of using a phrase “may have a substituent”, the type of the substituent, the position of the substituent, and the number of such substituents are not particularly limited. The number of the substituents may be, for example, one, two, three, or more. Examples of the substituent include monovalent non-metallic atomic groups excluding a hydrogen atom and, for example, can be selected from substituent T below.

### Substituent T

Examples of substituent T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; cycloalkyl groups; aryl groups; heteroaryl groups; a hydroxy group; a carboxy group; a formyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; a nitro group; and combinations of the foregoing.

The bonding direction of a divalent group expressed in the present specification is not limited unless otherwise specified. For example, in a compound represented by a general formula “L-M-N” where M is —OCO—C(CN)═CH—, when a position bonded to the L side is represented by *1 and a position bonded to the N side is represented by *2, M may be *1-OCO—C(CN)═CH—*2 or * 1—CH═C(CN)—COO—*2.

In the present specification, “(meth)acrylic” is a collective term for “acrylic” and “methacrylic” and means “at least one of acrylic or methacrylic”. Similarly, “(meth)acrylic acid” is a collective term for “acrylic acid” and “methacrylic acid” and means “at least one of acrylic acid or methacrylic acid”.

In the present specification, a weight-average molecular weight (Mw), a number-average molecular weight (Mn), a Z-average molecular weight (Mz), and a molecular weight distribution (also referred to as a “dispersity”) (Mw/Mn) of a resin are defined as polystyrene equivalent values determined, using a gel permeation chromatography (GPC) apparatus (HLC-8120GPC manufactured by Tosoh Corporation), by GPC measurement (solvent: tetrahydrofuran, amount of flow (amount of sample injected): 10 μL, column: TSK gel Multipore HXL-M manufactured by Tosoh Corporation, column temperature: 40° C., flow rate: 1.0 mL/min, detector: differential refractive index detector).

In the present specification, “actinic ray” or “radiation” means, for example, an emission line spectrum of a mercury lamp, far ultraviolet rays represented by an excimer laser, extreme ultraviolet rays (EUV), X-rays, or an electron beam (EB). In the present specification, “light” means an actinic ray or a radiation.

In the present specification, “exposure” includes, unless otherwise specified, not only exposure with, for example, an emission line spectrum of a mercury lamp, far ultraviolet rays represented by an excimer laser, extreme ultraviolet rays (EUV), or X-rays but also patterning with an electron beam or a corpuscular beam such as an ion beam.

### Actinic Ray-Sensitive or Radiation-Sensitive Resin Composition

An actinic ray-sensitive or radiation-sensitive resin composition according to the present invention (hereinafter, also referred to as a “composition according to the present invention”) includes
a resin (A) that undergoes an increase in alkali solubility due to action of acid,
a compound (C) that generates acid upon irradiation with an actinic ray or radiation, and
a solvent (S) including a solvent SA having a boiling point of 130° C. to 150° C. and a solvent SB having a boiling point of 155° C. to 250° C.,
in which a content of the solvent SA is higher than a content of the solvent SB, the content of the solvent SB relative to the whole solvent is 1% to 30% by mass, and
a concentration of solid contents is 10% by mass or more.

The reason why the composition according to the present invention has a good EL performance has not been completely clarified, but the inventors of the present presume as follows.

As a result of studies conducted by the inventors of the present invention, it has been revealed that when two or more solvents are used in an actinic ray-sensitive or radiation-sensitive resin composition, the solvents are likely to remain in the resulting actinic ray-sensitive or radiation-sensitive film depending on the combination and the blending amounts thereof, and as a result, the exposure latitude (EL) performance is deteriorated in some cases. Specifically, it has been found that when a solvent having a boiling point close to or lower than that of a solvent mainly used is mixed and used as an auxiliary solvent, the solvents tend to remain in the film, resulting in deterioration of the EL performance. In has been found that, in particular, when the thickness of the actinic ray-sensitive or radiation-sensitive film formed is large to a certain extent or more (for example, when the thickness is 0.5 nm or more), the above tendency becomes significant.

Probably, if the actinic ray-sensitive or radiation-sensitive film contains a large amount of residual solvent, the film is softened, an acid generated from a compound (photoacid generator) that generates acid upon irradiation with an actinic ray or radiation and that is included in the film is likely to diffuse, and the diffusion length varies, resulting in deterioration of the EL performance.

The composition according to the present invention contains, as solvents, a solvent SA having a boiling point of 130° C. to 150° C. and a solvent SB having a content smaller than that of the solvent SA in a predetermined amount. The boiling point of the solvent SB is 155° C. to 250° C., which is higher than the boiling point of the solvent SA. The addition of the solvent SB enables the promotion of the volatilization of the solvent SA during the formation of the actinic ray-sensitive or radiation-sensitive film, more specifically, during the drying after application of the actinic ray-sensitive or radiation-sensitive resin composition to reduce the amount of residual solvent in the film. It is considered that, as a result, the diffusion length of the acid in the film is shortened and uniformized, and the EL performance is improved.

In general, when the amount of residual solvent is to be reduced, an addition of a solvent having a low boiling point and high volatility is considered; however in the present invention, a predetermined amount of the solvent SB having a higher boiling point is intentionally added. As a result, surprisingly, it has been found that the volatilization of the solvent SA can be promoted to reduce the amount of residual solvent.

The actinic ray-sensitive or radiation-sensitive resin composition according to the present invention is typically a resist composition (preferably a chemical amplification resist composition) and may be a positive resist composition or a negative resist composition, but is preferably a positive resist composition. The actinic ray-sensitive or radiation-sensitive resin composition according to the present invention may be a resist composition for alkali development or a resist composition for organic solvent development, but is preferably a resist composition for alkali development.

(A) Resin that undergoes increase in alkali solubility due to action of acid

A resin (A) that undergoes an increase in alkali solubility due to action of acid (also simply referred to as a “resin (A)”) and that is included in the composition according to the present invention will be described.

The resin (A) is a resin that undergoes an increase in alkali solubility due to the action of acid, is preferably a resin having an acid-decomposable group, and more preferably has a repeating unit having an acid-decomposable group.

The acid-decomposable group refers to a group that is decomposed due to the action of acid to generate a polar group. The acid-decomposable group preferably has a structure in which the polar group is protected with a group (leaving group) that leaves due to the action of acid. That is, the resin (A) preferably has a repeating unit having a group that is decomposed due to the action of acid to generate a polar group. The resin (A) is preferably a resin whose polarity is increased by the action of acid to have increased solubility in an alkali developer and decreased solubility in an organic solvent.

The polar group is preferably an alkali-soluble group. Examples thereof include acid groups such as a carboxyl group, a phenolic hydroxy group, fluorinated alcohol groups, a sulfonic group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxy group.

The phenolic hydroxy group refers to a hydroxy group bonded to an aromatic hydrocarbon ring.

The polar group is preferably a carboxyl group, a phenolic hydroxy group, a fluorinated alcohol group (preferably a hexafluoroisopropanol group), or a sulfonic group.

Examples of the group (leaving group) that leaves due to the action of acid include groups represented by formulae (Y1) to (Y4).

—C(Rx₁)(Rx₂)(Rx₃) Formula (Y1)

—C(═O)OC(Rx₁)(Rx₂)(Rx₃) Formula (Y2)

—C(R₃₆)(R₃₇)(OR₃₈) Formula (Y3)

—C(Rn)(H)(Ar) Formula (Y4)

In formulae (Y1) and (Y2), Rx₁ to Rx₃ each independently represent an alkyl group (linear or branched) or a cycloalkyl group (monocyclic or polycyclic). Note that, when Rx₁ to Rx₃ are all alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be linked together to form a monocycle or a polycycle.

The alkyl group in Rx₁ to Rx₃ is preferably an alkyl group having 1 to 4 carbon atoms such as a methyl group, an ethyl group, a n-propyl group, an isopropyl group, a n-butyl group, an isobutyl group, or a tert-butyl group.

The cycloalkyl group in Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The cycloalkyl group formed by linking two of Rx₁ to Rx₃ together is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, more preferably a monocyclic cycloalkyl group having 5 to 6 carbon atoms.

In the cycloalkyl group formed by linking two of Rx₁ to Rx₃ together, for example, one of methylene groups forming the ring may be replaced by a heteroatom such as an oxygen atom, or a group having a heteroatom, such as a carbonyl group.

The group represented by formula (Y1) or formula (Y2) preferably has a form in which, for example, Rx₁ is a methyl group or an ethyl group, and Rx₂ and Rx₃ are linked together to form the above-described cycloalkyl group.

In formula (Y3), R₃₆ to R₃₈ each independently represent a hydrogen atom or a monovalent substituent. R₃₇ and R₃₈ may be linked together to form a ring. Examples of the monovalent substituent include, but are not particularly limited to, alkyl groups, cycloalkyl groups, aryl groups, aralkyl groups, and alkenyl groups. It is also preferable that R₃₆ be a hydrogen atom.

Formula (Y3) is preferably a group represented by the following formula (Y3-1).

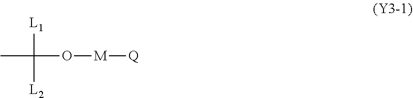

Here, L₁ and L₂ each independently represent a hydrogen atom, an alkyl group, a cycloalkyl group, an aryl group, or a group of a combination of the foregoing (for example, a group of a combination of an alkyl group and an aryl group).

M represents a single bond or a divalent linking group.

Q represents an alkyl group that may have a heteroatom, a cycloalkyl group that may have a heteroatom, an aryl group that may have a heteroatom, an amino group, an ammonium group, a mercapto group, a cyano group, an aldehyde group, or a group of a combination of the foregoing (for example, a group of a combination of an alkyl group and a cycloalkyl group).

In the alkyl group and the cycloalkyl group, for example, one of methylene groups may be replaced by a heteroatom such as an oxygen atom or a group having a heteroatom, such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two of Q, M, and L₁ may be linked together to form a ring (preferably a five-membered or six-membered ring).

From the viewpoint of forming a finer pattern, L₂ is preferably a secondary or tertiary alkyl group, more preferably a tertiary alkyl group. Examples of the secondary alkyl group include an isopropyl group, a cyclohexyl group, and a norbornyl group. Examples of the tertiary alkyl group include a tert-butyl group and an adamantane ring group. In such forms, since Tg (glass transition temperature) and activation energy are increased, the film hardness is ensured, and fog can be suppressed.

In formula (Y4), Ar represents an aromatic ring group. Rn represents an alkyl group, a cycloalkyl group, or an aryl group. Rn and Ar may be linked together to form a non-aromatic ring. Ar is more preferably an aryl group.

The repeating unit having an acid-decomposable group is preferably at least one of a repeating unit represented by the following general formula (Aa1) or a repeating unit represented by the following general formula (IIa).

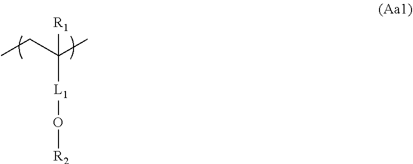

In general formula (Aa1), L₁ represents a divalent linking group, R₁ represents a hydrogen atom, a fluorine atom, an iodine atom, an alkyl group, or an aryl group, and R₂ represents a group that leaves due to the action of acid.

L₁ represents a divalent linking group. Examples of the divalent linking group include —CO—, —O—, —S—, —SO—, —SO₂—, hydrocarbon groups (such as alkylene groups, cycloalkylene groups, alkenylene groups, and arylene groups), and linking groups provided by linking a plurality of the foregoing together. The hydrocarbon groups may have a substituent.

L₁ is preferably —CO—, an alkylene group, or an arylene group.

The arylene group is preferably an arylene group having 6 to 20 carbon atoms, more preferably an arylene group having 6 to 10 carbon atoms, still more preferably a phenylene group.

The alkylene group may be linear or branched. The number of carbon atoms of the alkylene group is not particularly limited, but is preferably 1 to 10, more preferably 1 to 3. The arylene group preferably has a fluorine atom or an iodine atom. The total number of fluorine atoms and iodine atoms included in the alkylene groups is not particularly limited, but is preferably 2 or more, more preferably 2 to 10, still more preferably 3 to 6.

R₁ represents a hydrogen atom, a fluorine atom, an iodine atom, an alkyl group, or an aryl group.

The alkyl group may be linear or branched. The number of carbon atoms of the alkyl group is not particularly limited, but is preferably 1 to 10, more preferably 1 to 3.

When the alkyl group has a fluorine atom or an iodine atom, the total number of fluorine atoms and iodine atoms included in the alkyl group is not particularly limited, but is preferably 1 or more, more preferably 1 to 5, still more preferably 1 to 3.

The alkyl group may have a heteroatom, such as an oxygen atom, other than a halogen atom.

R₂ represents a group (leaving group) that leaves due to the action of acid.

Examples of the leaving group include the above-described groups represented by formulae (Y1) to (Y4), and preferred ranges thereof are also the same as those described above.

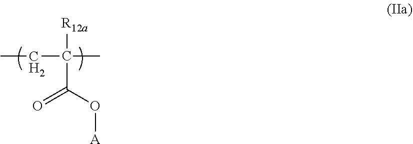

In general formula (IIa), R₁₂ₐ represents a hydrogen atom or a methyl group. A represents a group (leaving group) that leaves due to the action of acid.

Examples of the leaving group include the above-described groups represented by formulae (Y1) to (Y4), and preferred ranges thereof are also the same as those described above.

Because of a high dissolution contrast before and after deprotection, the repeating unit having an acid-decomposable group and included in the resin (A) is preferably a repeating unit represented by general formula (IIa) above.

The resin (A) may have only one kind of repeating unit having an acid-decomposable group or two or more kinds of repeating units having an acid-decomposable group.

A content G_{A} of the repeating unit having an acid-decomposable group (a total content when two or more kinds of repeating units having an acid-decomposable group are included) in the resin (A) is, on a molar basis, preferably 70% by mole or less, more preferably 50% by mole or less, still more preferably 30% by mole or less, particularly preferably 10% by mole or more and 30% by mole or less, most preferably 20% by mole or more and 30% by mole or less relative to all the repeating units in the resin (A).

The resin (A) may have other repeating units in addition to the repeating unit having an acid-decomposable group.

When the resin (A) has another repeating unit in addition to the repeating unit having an acid-decomposable group, the content of the other repeating unit (the total content when two or more kinds of other repeating units are included) in the resin (A) is, on a molar basis, preferably 30% by mole or more and 90% by mole or less, more preferably 50% by mole or more and 90% by mole or less, particularly preferably 70% by mole or more and 80% by mole or less relative to all the repeating units in the resin (A).

Hereinafter, the other repeating units will be described.

### Repeating Unit Having Acid Group

The resin (A) may have a repeating unit having an acid group.

The repeating unit having an acid group is preferably a repeating unit represented by the following general formula (B).

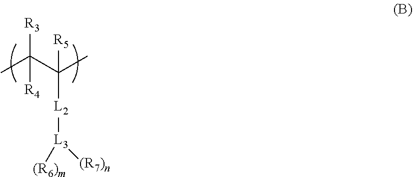

R₃ represents a hydrogen atom or a monovalent substituent. The monovalent substituent may have a fluorine atom or an iodine atom. The monovalent substituent is preferably a group represented by -L₄₀-R₈. L₄₀ represents a single bond or an ester group. R₈ is an alkyl group that may have a fluorine atom or an iodine atom, a cycloalkyl group that may have a fluorine atom or an iodine atom, an aryl group that may have a fluorine atom or an iodine atom, or a group of a combination of the foregoing.

R₄ and R₅ each independently represent a hydrogen atom, a fluorine atom, an iodine atom, or an alkyl group that may have a fluorine atom or an iodine atom.

L₂ represents a single bond or an ester group.

L₃ represents an (n+m+1) valent aromatic hydrocarbon ring group or an (n+m+1) valent alicyclic hydrocarbon ring group. The aromatic hydrocarbon ring group may be a benzene ring group or a naphthalene ring group. The alicyclic hydrocarbon ring group may be monocyclic or polycyclic and may be, for example, a cycloalkyl ring group.

R₆ represents a hydroxy group or a fluorinated alcohol group (preferably a hexafluoroisopropanol group). When R₆ is a hydroxy group, L₃ is preferably an (n+m+1) valent aromatic hydrocarbon ring group.

R₇ represents a halogen atom. The halogen atom may be a fluorine atom, a chlorine atom, a bromine atom, or an iodine atom.

m represents an integer of 1 or more. m is preferably an integer of 1 to 3, more preferably an integer of 1 or 2.

n represents 0 or an integer of 1 or more. n is preferably an integer of 1 to 4.

Note that (n+m+1) is preferably an integer of 1 to 5.

The repeating unit having an acid group is also preferably a repeating unit represented by the following general formula (I).

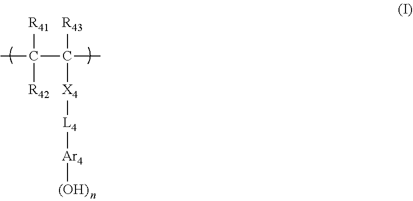

In general formula (I),
R₄₁, R₄₂ and R₄₃ each independently represent a hydrogen atom, an alkyl group, a cycloalkyl group, a halogen atom, a cyano group, or an alkoxycarbonyl group. However, R₄₂ may be linked to Ar₄ to form a ring, and in such a case, R₄₂ represents a single bond or an alkylene group.
X₄ represents a single bond, —COO— or a-CONR₆₄—, and R₆₄ represents a hydrogen atom or an alkyl group.

L₄ represents a single bond or an alkylene group.

Ar₄ represents an (n+1) valent aromatic ring group, and when Ar₄ is linked to R₄₂ to form a ring, Ar₄ represents an (n+2) valent aromatic ring group.

n represents an integer of 1 to 5.

In R₄₁ R₄₂, and R₄₃ in general formula (I), the alkyl group is preferably an alkyl groups having 20 or less carbon atoms, such as a methyl group, an ethyl group, a propyl group, an isopropyl group, a n-butyl group, a sec-butyl group, a hexyl group, a 2-ethylhexyl group, an octyl group, or a dodecyl group, more preferably an alkyl group having 8 or less carbon atoms, still more preferably an alkyl group having 3 or less carbon atoms.

In R₄₁, R₄₂, and R₄₃ in general formula (I), the cycloalkyl group may be monocyclic or polycyclic. In particular, monocyclic cycloalkyl groups having 3 to 8 carbon atoms, such as a cyclopropyl group, a cyclopentyl group, and a cyclohexyl group, are preferred.

In R₄₁, R₄₂, and R₄₃ in general formula (I), the halogen atom may be a fluorine atom, a chlorine atom, a bromine atom, or an iodine atom, and is preferably a fluorine atom.

The alkyl group included in the alkoxycarbonyl group of R₄₁, R₄₂, and R₄₃ in general formula (I) is preferably the same as the foregoing alkyl group in R₄₁, R₄₂, and R₄₃.

Ar₄ represents an (n+1) valent aromatic ring group. The divalent aromatic ring group when n is 1 may have a substituent, and is preferably, for example, an arylene group having 6 to 18 carbon atoms, such as a phenylene group, a tolylene group, a naphthylene group, or an anthracenylene group, or an aromatic ring group including a heterocycle, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring.

Specific examples of the (n+1) valent aromatic ring group when n is an integer of 2 or more include groups provided by removing any (n−1) hydrogen atoms from the foregoing specific examples of the divalent aromatic ring group. The (n+1) valent aromatic ring group may further have a substituent.

Examples of substituents that the foregoing alkyl groups, cycloalkyl groups, alkoxycarbonyl groups, alkylene groups, and the (n+1) valent aromatic ring groups can have include the alkyl groups described in R₄₁, R₄₂, and R₄₃ in general formula (I); alkoxy groups such as a methoxy group, an ethoxy group, a hydroxyethoxy group, a propoxy group, a hydroxypropoxy group, and a butoxy group; aryl groups such as a phenyl group.

Examples of the alkyl group of R₆₄ in —CONR₆₄— (where R₆₄ represents a hydrogen atom or an alkyl group) represented by X₄ include alkyl groups having 20 or less carbon atoms, such as a methyl group, an ethyl group, a propyl group, an isopropyl group, a n-butyl group, a sec-butyl group, a hexyl group, a 2-ethylhexyl group, an octyl group, and a dodecyl group. Of these, alkyl groups having 8 or less carbon atoms are preferred.

X₄ is preferably a single bond, —COO—, or —CONH—, more preferably a single bond or —COO—.

The alkylene group in L₄ is preferably an alkylene group having 1 to 8 carbon atoms, such as a methylene group, an ethylene group, a propylene group, a butylene group, a hexylene group, or an octylene group.

Arₙ is preferably an aromatic ring group having 6 to 18 carbon atoms, more preferably a benzene ring group, a naphthalene ring group, or a biphenylene ring group.

The repeating unit having an acid group is preferably a repeating unit having a phenolic hydroxy group, more preferably a repeating unit represented by general Formula (I) above.

The repeating unit having an acid group is preferably a repeating unit having a phenolic hydroxy group, more preferably a repeating unit represented by the following general formula (Ia).

The repeating unit represented by general formula (I) above is more preferably a repeating unit represented by the following general formula (Ia).

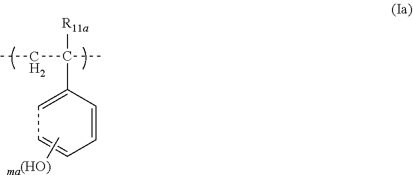

In general formula (Ia), R₁₁ₐ represents a hydrogen atom or a methyl group. ma represents 1 or 2.

Repeating unit (A-2) having at least one selected from the group consisting of lactone structure, sultone structure, carbonate structure, and hydroxyadamantane structure

The resin (A) may have a repeating unit (A-2) having at least one selected from the group consisting of a lactone structure, a carbonate structure, a sultone structure, and a hydroxyadamantane structure.

The lactone structure or the sultone structure in the repeating unit having a lactone structure or a sultone structure is not particularly limited, but is preferably a five- to seven-membered lactone structure or a five- to seven-membered sultone structure, more preferably a five- to seven-membered lactone structure to which another ring structure is fused so as to form a bicyclo structure or a spiro structure, or a five- to seven-membered sultone structure to which another ring structure is fused so as to form a bicyclo structure or a spiro structure.

Examples of the repeating unit having a lactone structure or a sultone structure include the repeating units described in paragraphs 0094 to 0107 of WO2016/136354A.

The resin (A) may have a repeating unit having a carbonate structure. The carbonate structure is preferably a cyclic carbonate structure.

Examples of the repeating unit having a carbonate structure include the repeating units described in paragraphs 0106 to 0108 of WO2019/054311A.

### Repeating Unit Having Fluorine Atom or Iodine Atom

The resin (A) may have a repeating unit having a fluorine atom or an iodine atom.

Examples of the repeating unit having a fluorine atom or an iodine atom include the repeating units described in paragraphs 0076 to 0081 of JP2019-045864A.

### Repeating Unit Having Photoacid Generating Group

The resin (A) may have, as a repeating unit other than the foregoing, a repeating unit having a photoacid generating group (a group that generates acid upon irradiation with an actinic ray or radiation).

Examples of the repeating unit having a photoacid generating group include the repeating units described in paragraphs 0092 to 0096 of JP2019-045864A.

### Repeating Unit Having Alkali-Soluble Group

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted with an electron-withdrawing group at the α-position (for example, a hexafluoroisopropanol group), and is preferably a carboxyl group. When the resin (A) has a repeating unit having an alkali-soluble group, the resolution increases in the contact hole application.

The repeating unit having an alkali-soluble group may be a repeating unit in which an alkali-soluble group is directly bonded to the main chain of a resin, such as a repeating unit derived from acrylic acid or methacrylic acid, or a repeating unit in which an alkali-soluble group is bonded to the main chain of a resin through a linking group. The linking group may have a monocyclic or polycyclic cyclic hydrocarbon structure.

The repeating unit having an alkali-soluble group is preferably a repeating unit derived from acrylic acid or methacrylic acid.

### Repeating Unit Having Neither Acid-Decomposable Group Nor Polar Group

The resin (A) may further have a repeating unit having neither an acid-decomposable group nor a polar group. The repeating unit having neither an acid-decomposable group nor a polar group is preferably a repeating unit represented by the following general formula (IIIa).

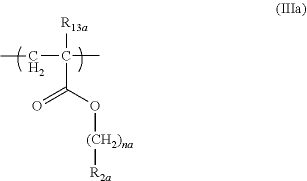

In general formula (IIIa), R₁₃ₐ represents a hydrogen atom or a methyl group. R₂ₐ represents a cyclic group. na represents an integer of 0 to 2.

The cyclic group represented by R₂ₐ may be an alicyclic group or an aromatic ring group. The cyclic group may be monocyclic or polycyclic.

The alicyclic group may be, for example, a cycloalkyl group or a cycloalkane having 3 to 20 carbon atoms, and is preferably a cyclohexyl group, a cyclopentyl group, or a decahydronaphthalenyl group.

The aromatic ring group may be, for example, an aryl group having 6 to 18 carbon atoms or a tolyl group, and is preferably a phenyl group, a benzene ring group, or a naphthalene ring group.

na represents an integer of 0 to 2, and is preferably 0 or 1.

The repeating unit having neither an acid-decomposable group nor a polar group preferably has an alicyclic hydrocarbon structure.

Examples of the repeating unit having neither an acid-decomposable group nor a polar group include the repeating units described in paragraphs 0236 and 0237 of US2016/0026083A and the repeating units described in paragraph 0433 of US2016/0070167A.

The resin (A) may have, in addition to the foregoing repeating units, various repeating units for the purpose of adjusting, for example, dry etching resistance, suitability for a standard developer, substrate adhesiveness, resist profile, resolving power, heat resistance, and sensitivity.

The resin (A) is preferably a resin containing a repeating unit having an acid-decomposable group and a repeating unit having a phenolic hydroxy group, more preferably a resin containing a repeating unit represented by general formula (Ia) above, a repeating unit represented by general formula (IIa) above, and a repeating unit represented by general formula (IIIa) above.

The resin (A) can be synthesized by an ordinary method (for example, radical polymerization).

The resin (A) has a weight-average molecular weight (Mw_{A}) of preferably 1,000 to 200,000, more preferably 3,000 to 50,000, still more preferably 5,000 to 30,000. Note that Mw_{A} is a polystyrene equivalent value determined by the GPC method described above.

The molecular weight distribution (Mw_{A}/Mn_{A}) of the resin (A), which is a value obtained by dividing Mw_{A} by the number-average molecular weight Mn_{A} of the resin (A), is usually 1.00 to 5.00, preferably 1.00 to 3.00, more preferably 1.10 to 2.00.

A content (S_{A}) of the resin (A) relative to the total solid content in the composition according to the present invention is, on a mass basis, preferably 40% to 99% by mass, more preferably 50% to 99% by mass, still more preferably 80% to 99% by mass.

In the present specification, the solid content means components other than solvents. Even if the components are in the form of liquid, the components are regarded as the solid content. The total solid content mean the sum of all solid contents.

Compound that Generates Acid Upon Irradiation with Actinic Ray or Radiation (Photoacid Generator)

The composition according to the present invention contains a compound that generates acid upon irradiation with an actinic ray or radiation (also referred to as a “photoacid generator (C)”).

The photoacid generator (C) may be any compound that generates acid upon irradiation with an actinic ray or radiation.

The photoacid generator (C) may have the form of a low-molecular-weight compound or the form of being incorporated into a portion of a polymer. Alternatively, the form of a low-molecular-weight compound and the form of being incorporated into a portion of a polymer may be used in combination.

When the photoacid generator (C) has the form of a low-molecular-weight compound, the weight-average molecular weight (Mw) of the photoacid generator (C) is preferably 3,000 or less, more preferably 2,000 or less, still more preferably 1,000 or less.

The photoacid generator (C) may be incorporated into a portion of the resin (A) or may be incorporated into a resin different from the resin (A).

The photoacid generator (C) preferably has the form of a low-molecular-weight compound.

The photoacid generator (C) is preferably an ionic compound including a cation and an anion.

The photoacid generator (C) is preferably a compound that generates an organic acid upon irradiation with an actinic ray or radiation, more preferably a compound that generates an organic acid upon irradiation with an actinic ray or radiation and that has a fluorine atom or an iodine atom in the molecule. Examples of the organic acid include sulfonic acids (such as aliphatic sulfonic acids, aromatic sulfonic acids, and camphor sulfonic acid), carboxylic acids (such as aliphatic carboxylic acids, aromatic carboxylic acids, and aralkyl carboxylic acids), carbonylsulfonylimidic acid, bis(alkylsulfonyl)imidic acids, and tris(alkylsulfonyl)methide acids.

Examples of suitable forms of the photoacid generator (C) include a compound represented by the following general formula (ZI), a compound represented by the following general formula (ZII), and a compound represented by the following general formula (ZIII).

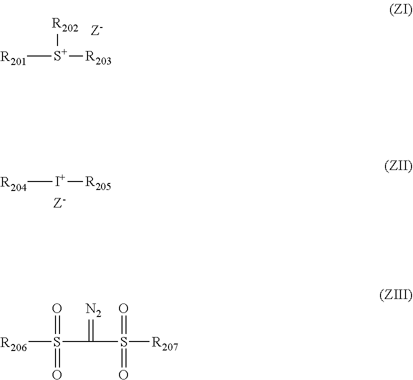

In general formula (ZI) above,
R₂₀₁, R₂₀₂, and R₂₀₃ each independently represent an organic group.

The number of carbon atoms of each of the organic groups serving as R₂₀₁, R₂₀₂, and R₂₀₃ is preferably 1 to 30, more preferably 1 to 20.

Two of R₂₀₁ to R₂₀₃ may be linked together to form a ring structure, and the ring may include an oxygen atom, a sulfur atom, an ester bond, an amide bond, or a carbonyl group. Examples of the group formed by linking two of R₂₀₁ to R₂₀₃ include alkylene groups (such as a butylene group and a pentylene group) and —CH₂—CH₂—O—CH₂—CH₂—.

Z₋ represents an anion.

Cation in compound represented by general formula (ZI)

Suitable forms of the cation in general formula (ZI) include corresponding groups in compounds (ZI-1), (ZI-2), (ZI-3), and (ZI-4) which will be described later.

The photoacid generator (C) may be a compound having a plurality of structures represented by general formula (ZI). For example, the photoacid generator (C) may be a compound having a structure in which at least one of R₂₀₁ to R₂₀₃ of a compound represented by general formula (ZI) and at least one of R₂₀₁ to R₂₀₃ of another compound represented by general formula (ZI) are bonded to each other through a single bond or a linking group.

### Compound (ZI-1)

The compound (ZI-1) is an arylsulfonium compound in which at least one of R₂₀₁ to R₂₀₃ in general formula (ZI) above is an aryl group, that is, a compound having an arylsulfonium as a cation.

In the arylsulfonium compound, all of R₂₀₁ to R₂₀₃ may be aryl groups, or some of R₂₀₁ to R₂₀₃ may be aryl groups and the remainder may be an alkyl group or a cycloalkyl group.

Examples of the arylsulfonium compound include triarylsulfonium compounds, diarylalkylsulfonium compounds, aryldialkylsulfonium compounds, diarylcycloalkylsulfonium compounds, and aryldicycloalkylsulfonium compounds.

### Compound (ZI-2)

The compound (ZI-2) is a compound in which R₂₀₁ to R₂₀₃ in general formula (ZI) each independently represent an organic group having no aromatic ring. Herein, the aromatic ring also encompasses aromatic rings containing heteroatoms.

In R₂₀₁ to R₂₀₃, the organic group having no aromatic ring generally has 1 to 30 carbon atoms, preferably 1 to 20 carbon atoms.

R₂₀₁ to R₂₀₃ each independently represent preferably an alkyl group, a cycloalkyl group, an allyl group, or a vinyl group, more preferably a linear or branched 2-oxoalkyl group, a 2-oxocycloalkyl group, or an alkoxycarbonylmethyl group, still more preferably a linear or branched 2-oxoalkyl group.

### Compound (ZI-3)

The compound (ZI-3) is a compound represented by the following general formula (ZI-3) and having a phenacylsulfonium salt structure.

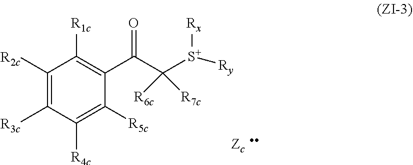

In general formula (ZI-3),
R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.
R_{6c}, and R_{7c}, each independently represent a hydrogen atom, an alkyl group, a cycloalkyl group, a halogen atom, a cyano group, or an aryl group.
Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c}, to R_{5c}, R_{5c} and R_{6c}, R_{6c} and R_{7c}, R_{5c} and Rₓ, and Rₓ and R_{y} may be individually linked together to form ring structures, and the ring structures may each independently include an oxygen atom, a sulfur atom, a ketone group, an ester bond, or an amide bond.

Zc₋ represents an anion.

### Compound (ZI-4)

Next, the compound (ZI-4) will be described.

The compound (ZI-4) is represented by the following general formula (ZI-4).

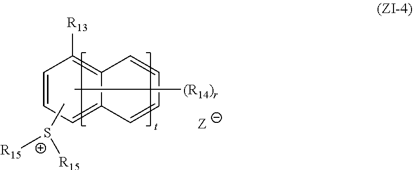

In general formula (ZI-4),
1 represents an integer of 0 to 2.
r represents an integer of 0 to 8.
R₁₃ represents a hydrogen atom, a fluorine atom, a hydroxy group, an alkyl group, a cycloalkyl group, an alkoxy group, or an alkoxycarbonyl group.
R₁₄ represents a hydroxyl group, an alkyl group, a cycloalkyl group, an alkoxy group, an alkoxycarbonyl group, an alkylcarbonyl group, an alkylsulfonyl group, or a cycloalkylsulfonyl group. When a plurality of R₁₄'s are present, they may be the same or different.
R₁₅'s each independently represent an alkyl group, a cycloalkyl group, or a naphthyl group. Two R₁₅'s may be linked together to form a ring. When two R₁₅'s are linked together to form a ring, the ring skeleton may include a heteroatom such as an oxygen atom or a nitrogen atom.

Z₋ represents an anion.

Cation in compound represented by general formula (ZII) or general formula (ZIII)

Next, general formulae (ZII) and (ZIII) will be described.

In general formulae (ZII) and (ZIII), R₂₀₄ to R₂₀₇ each independently represent an aryl group, an alkyl group, or a cycloalkyl group.

In R₂₀₄ to R₂₀₇, the aryl group is preferably a phenyl group or a naphthyl group, more preferably a phenyl group. In R₂₀₄ to R₂₀₇, the aryl group may be an aryl group having a heterocyclic structure having, for example, an oxygen atom, a nitrogen atom, or a sulfur atom. Examples of the skeleton of the aryl group having a heterocyclic structure include pyrrole, furan, thiophene, indole, benzofuran, and benzothiophene.

In R₂₀₄ to R₂₀₇, the alkyl group and the cycloalkyl group are, for example, a linear alkyl group having 1 to 10 carbon atoms or a branched alkyl group having 3 to 10 carbon atoms (for example, a methyl group, an ethyl group, a propyl group, a butyl group, or a pentyl group), and a cycloalkyl group having 3 to 10 carbon atoms (for example, a cyclopentyl group, a cyclohexyl group, or a norbornyl group).

In R₂₀₄ to R₂₀₇, the aryl group, the alkyl group, and the cycloalkyl group may each independently have a substituent. Examples of the substituent that the aryl group, the alkyl group, and the cycloalkyl group in R₂₀₄ to R₂₀₇ may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group.

Z⁻ represents an anion.

Anion in compound represented by general formula (ZI), general formula (ZII), general formula (ZI-3), or general formula (ZI-4)

Z⁻ in general formula (ZI), Z⁻ in general formula (ZII), Zc⁻ in general formula (ZI-3), and Z⁻ in general formula (ZI-4) are each preferably an anion represented by the following general formula (3).

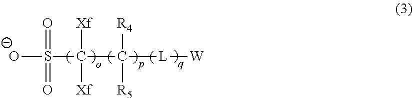

In general formula (3),
Xfs each independently represent a fluorine atom or an alkyl group substituted with at least one fluorine atom.
R₄ and R₅ each independently represent a hydrogen atom, a fluorine atom, an alkyl group, or an alkyl group substituted with at least one fluorine atom, and when a plurality of R₄'s and R₅'s are present, they may be the same or different.
L represents a divalent linking group, and when a plurality of L's are present, they may be the same or different.
W represents an organic group.
represents an integer of 1 to 3. p represents an integer of 0 to 10. q represents an integer of 0 to 10.

Xfs each represent a fluorine atom or an alkyl group substituted with at least one fluorine atom. The number of carbon atoms of the alkyl group is preferably 1 to 10, more preferably 1 to 4. The alkyl group substituted with at least one fluorine atom is preferably a perfluoroalkyl group. The plurality of Xf's may be the same or different.

Xf is preferably a fluorine atom or a perfluoroalkyl group having 1 to 4 carbon atoms. Xf is more preferably a fluorine atom or CF₃. In particular, all Xf's are each a fluorine atom.

R₄ and R₅ each independently represent a hydrogen atom, a fluorine atom, an alkyl group, or an alkyl group substituted with at least one fluorine atom. When a plurality of R₄ and R₅ are present, they may be the same or different.

The alkyl groups serving as R₄ and R₅ may have substituents and preferably have 1 to 4 carbon atoms. R₄ and R₅ are preferably hydrogen atoms.

Specific examples and suitable forms of the alkyl group substituted with at least one fluorine atom are the same as specific examples and suitable forms of Xf in general formula (3).

L represents a divalent linking group, and when a plurality of L's are present, they may be the same or different.

Examples of the divalent linking group include —COO—(—C(═O)—O—), —OCO—, —CONH—, —NHCO—, —CO—, —O—, —S—, —SO—, —SO₂—, alkylene groups (preferably having 1 to 6 carbon atoms), cycloalkylene groups (preferably having 3 to 15 carbon atoms), alkenylene groups (preferably having 2 to 6 carbon atoms), and divalent linking groups provided by combining a plurality of the foregoing. Of these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferred, and —COO—, —OCO—, —CONH—, —SO₂—, —COO-alkylene group-, or —OCO-alkylene group- is more preferred.

W represents an organic group.

The number of carbon atoms of the organic group is not particularly limited, but is generally 1 to 30, preferably 1 to 20.

The organic group is not particularly limited, but represents, for example, an alkyl group or an alkoxy group.

W preferably represents an organic group including a cyclic structure. Among these, a cyclic organic group is preferred.

Examples of the cyclic organic group include alicyclic groups, aryl groups, and heterocyclic groups. The cyclic organic group may have a substituent.

Z⁻ in general formula (ZI), Z⁻ in general formula (ZII), Zc⁻ in general formula (ZI-3), and Z⁻ in general formula (ZI-4) are also each preferably an anion represented by the following general formula (An-2) or (An-3).

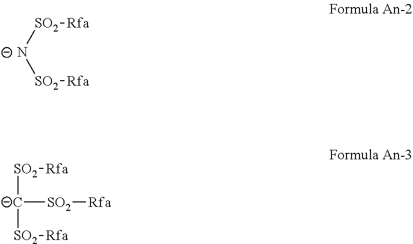

In general formulae (An-2) and (An-3), Rfa's each independently represent a monovalent organic group having a fluorine atom, and the plurality of Rfa's may be linked together to form a ring.

Rfa is preferably an alkyl group substituted with at least one fluorine atom. The number of carbon atoms of the alkyl group is preferably 1 to 10, more preferably 1 to 4. The alkyl group substituted with at least one fluorine atom is preferably a perfluoroalkyl group.

Preferred examples of a sulfonium cation in general formula (ZI) and a sulfonium cation or an iodonium cation in general formula (ZII) are shown below.

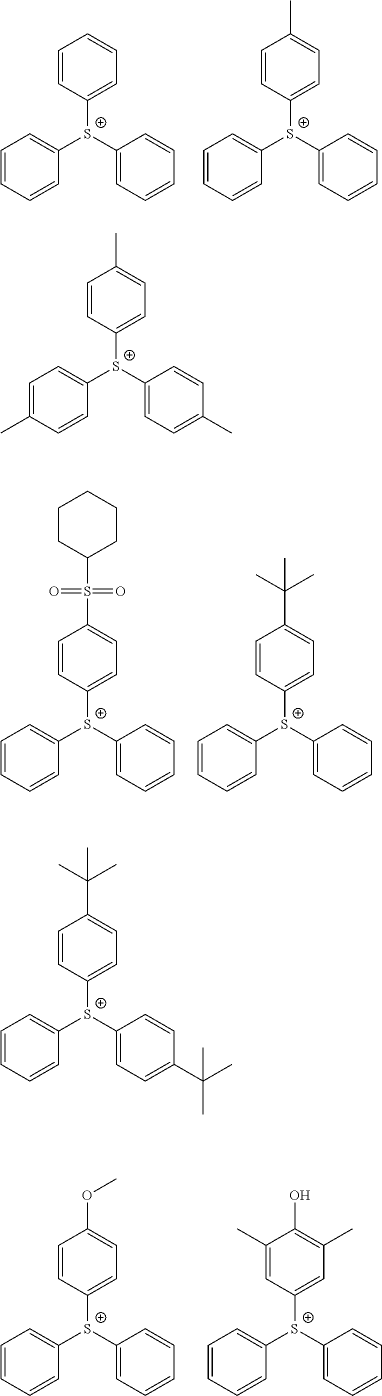

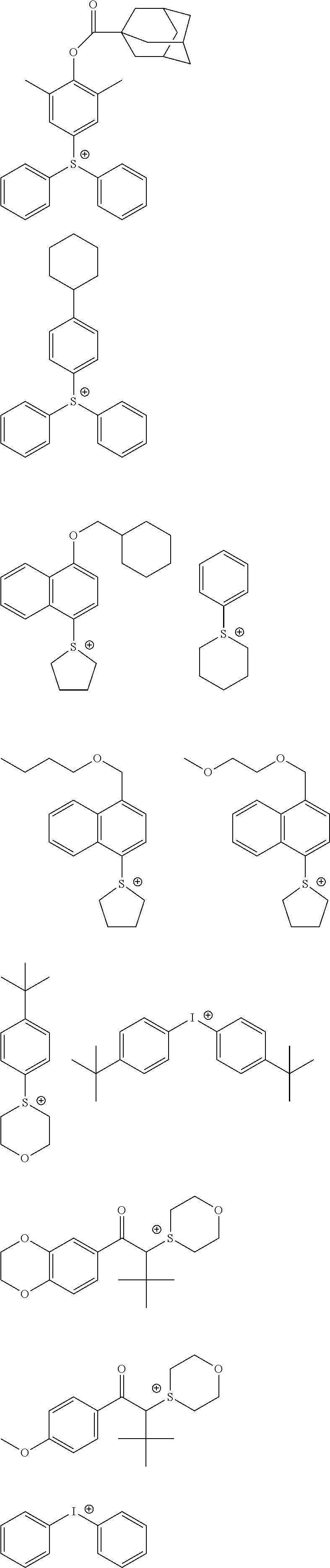

Preferred examples of the anion Z⁻ in general formula (ZI) and general formula (ZII), Zc⁻ in general formula (ZI-3), and Z⁻ in general formula (ZI-4) are shown below.

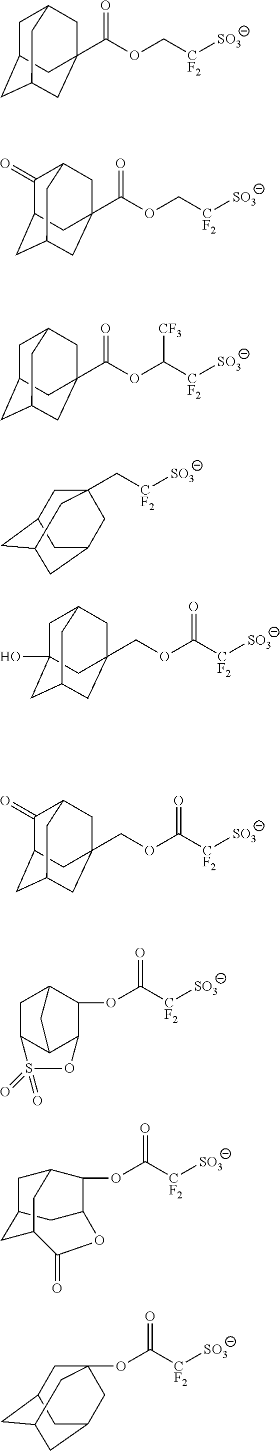

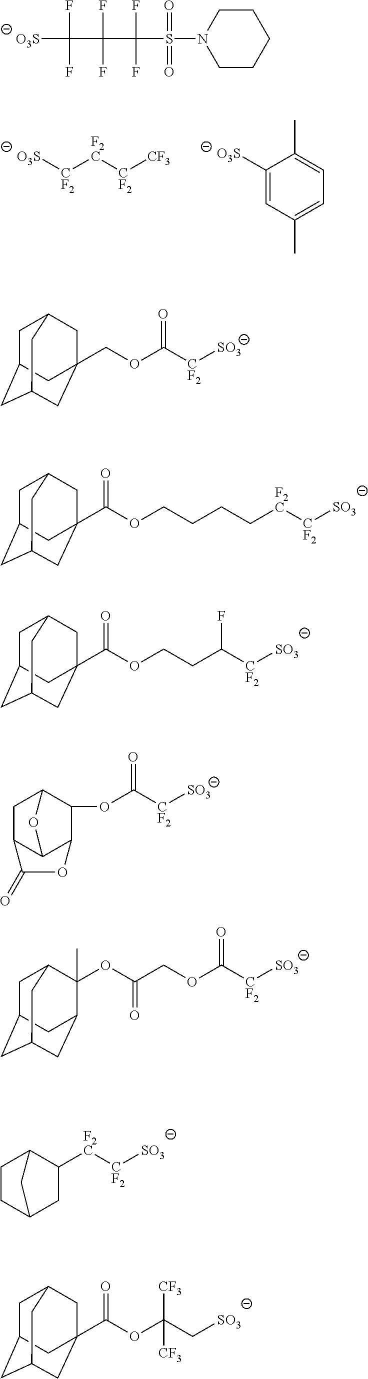

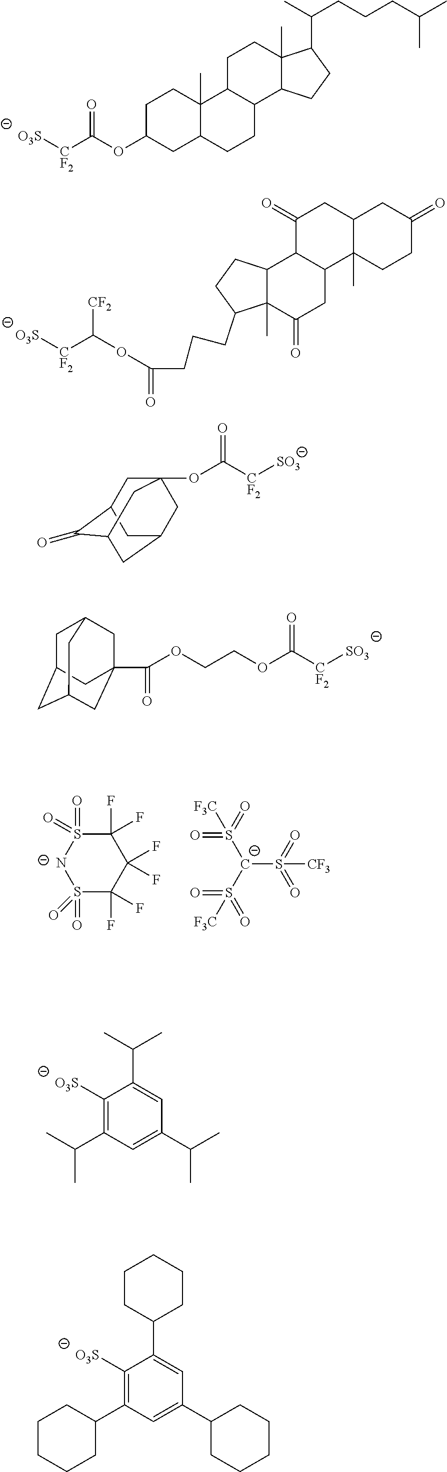

A publicly known photoacid generator can be appropriately used as the photoacid generator (C).

The content, by mass, of the photoacid generator (C) in the composition according to the present invention is preferably 0.100 to 20% by mass, more preferably 0.5% to 15% by mass, still more preferably 0.5% to 1000 by mass, particularly preferably 5% to 1000 by mass relative to the total solid content of the composition.

In particular, when the content of the photoacid generator (C) is 5% by mass or more, the EL performance can be further improved.

A mass ratio of the solvent SB described later to the photoacid generator (C) (solvent SB/photoacid generator (C)) is preferably 0.1 to 200, more preferably 1 to 100, still more preferably 1 to 50. When the mass ratio of the solvent SB to the photoacid generator (C) is 0.1 to 200, the EL performance can be further improved.

Such photoacid generators (C) may be used alone or in combination of two or more thereof. When two or more photoacid generators (C) are used in combination, the total amount thereof is preferably within the range described above.

### Acid Diffusion Control Agent (D)

The composition according to the present invention may include an acid diffusion control agent.

The acid diffusion control agent serves as a quencher that traps an acid generated from, for example, the photoacid generator upon exposure and that suppresses a reaction of the acid-decomposable resin in a non-exposed portion, the reaction being caused by an excess of the generated acid.

Examples of the kind of acid diffusion control agent include, but are not particularly limited to, a basic compound (DA), a low-molecular-weight compound (DB) having a nitrogen atom and having a group that leaves due to the action of acid, and a compound (DC) that undergoes a reduction or loss of the acid diffusion control ability upon irradiation with an actinic ray or radiation.

Examples of the compound (DC) include an onium salt compound (DD) that generates acid weaker than the photoacid generator, and a basic compound (DE) that undergoes a reduction or loss of the basicity upon irradiation with an actinic ray or radiation.

Specific examples of the basic compound (DA) include those described in paragraphs [0132] to [0136] of WO2020/066824A. Specific examples of the basic compound (DE) that undergoes a reduction or loss of the basicity upon irradiation with an actinic ray or radiation include those described in paragraphs [0137] to [0155] of WO2020/066824A and those described in paragraph [0164] of WO2020/066824A. Specific examples of the low-molecular-weight compound (DB) having a nitrogen atom and having a group that leaves due to the action of acid include those described in paragraphs [0156] to [0163] of WO2020/066824A. Specific examples of the onium salt compound (DD) that generates acid weaker than the photoacid generator include those described in paragraphs [0305] to [0314] of WO2020/158337A.

In addition to the above, publicly known compounds disclosed in, for example, paragraphs [0627] to [0664] of US2016/0070167A1, paragraphs [0095] to [0187] of US2015/0004544A1, paragraphs [0403] to [0423] of US2016/0237190A1, and paragraphs [0259] to [0328] of US2016/0274458A1 can be suitably used as the acid diffusion control agent.

In the composition according to the present invention, the content of the acid diffusion control agent (D) (the total content when a plurality of acid diffusion control agents are present) relative to the total solid content of the composition according to the present invention is preferably 0.01% to 10.0% by mass, more preferably 0.01% to 5.0% by mass.

In the present invention, such acid diffusion control agents (D) may be used alone or in combination of two or more thereof.

### Solvent (S)

The composition according to the present invention contains a solvent (also referred to as a “solvent (S)”).

The solvent (S) includes a solvent SA having a boiling point of 130° C. to 150° C. and a solvent SB having a boiling point of 155° C. to 250° C.

The content of the solvent SA in the composition according to the present invention is higher than the content of the solvent SB, and the content of the solvent SB relative to the whole solvent is 1% to 30% by mass.

The solvent (S) is preferably an organic solvent.

### Solvent SA

The solvent SA is not particularly limited as long as the solvent has a boiling point (T_{SA}) of 130° C. to 150° C. T_{SA} is preferably 135° C. to 150° C., more preferably 140° C. to 150° C.

The solubility parameter (SP value) of the solvent SA is preferably 7 to 15, more preferably 8 to 13 in view of affinity for (ease of mixing with) the polymer.

In the present invention, the SP value is derived using the Hansen's method. Here, in the Hansen's method, energy of one substance is represented by three components of a dispersion energy term (δ_{D}), a polarization energy term (δ_{P}), and a hydrogen-bond energy term (δ_{H}) and is represented as a vector in a three-dimensional space.

In the present invention, the solubility parameter is a value calculated using the software Hansen Solubility Parameters in Practice (HSPiP), ver. 4.1.07.

The SP value of each component is calculated based on the following formula (spa). The unit of the SP value is (J/cm³)^{1/2}.

[SP value]=(δ_{D}²+δ_{P}²+δ_{H}²)^{1/2} Formula (spa)

The molecular weight of the solvent SA is preferably 80 to 500, more preferably 100 to 200 from the viewpoint that the viscosity is preferably low.

The viscosity of the solvent SA is preferably 0.5 to 5.0 mPa·s, more preferably 1.0 to 3.5 mPa·s.

The viscosity of the solvent is determined by conducting measurement at 25° C. using an E-type viscometer (Model RE-85L, manufactured by Toki Sangyo Co., Ltd.).

The evaporation rate index of the solvent SA is preferably 20 to 100, more preferably 25 to 50.

The evaporation rate index of a solvent can be expressed using the following formula.

Evaporation rate index=k×P×M
k represents a constant 0.11 (20° C.).
P represents the vapor pressure (mmHg).
M represents the molecular weight of the solvent.

Examples of the solvent SA include aromatic hydrocarbon-based, ketone-based, glycol ether-based, and ester-based solvents.

An example of the aromatic hydrocarbon-based solvent is xylene (boiling point: 144° C., SP value: 8.6).

Examples of the ketone-based solvent include methyl isoamyl ketone (boiling point: 144° C., SP value: 8.1) and methyl amyl ketone (boiling point: 151° C., SP value: 8.3).

Examples of the glycol ether-based solvent include propylene glycol monoethyl ether (boiling point: 133° C., SP value: 10.8), propylene glycol mono-n-propyl ether (boiling point: 150° C., SP value: 10.5), propylene glycol monomethyl ether acetate (boiling point: 146° C., SP value: 8.8), ethylene glycol monoethyl ether (boiling point: 135° C., SP value: 11.4), and ethylene glycol monomethyl ether acetate (boiling point: 144° C., SP value: 9.1).

Examples of the ester-based solvent include methyl lactate (boiling point: 145° C., SP value: 12.7), methyl 3-methoxypropionate (boiling point: 142° C., SP value: 9.6), methyl pyruvate (boiling point: 135° C., SP value: 11.0), and ethyl pyruvate (boiling point: 144° C., SP value: 10.4).

Other examples include dibutyl ether (boiling point: 142° C., SP value: 7.8) and N,N-dimethylacetamide (boiling point: 165° C., SP value: 11.2).

The solvent SA is preferably propylene glycol monomethyl ether acetate, methyl lactate, propylene glycol monoethyl ether, methyl 3-methoxypropionate, or ethyl 3-ethoxypropionate, more preferably propylene glycol monomethyl ether acetate.

### Solvent SB

The solvent SB is a solvent having a boiling point (T_{SB}) of 155° C. to 250° C. The addition of the solvent SB enables the promotion of the volatilization of the solvent SA to reduce the amount of residual solvent in the actinic ray-sensitive or radiation-sensitive film. From the viewpoint of improving the effect of reducing the residual solvent in the film, T_{SB} is preferably 170° C. to 240° C., more preferably 180° C. to 220° C.

The solubility parameter (SP value) of the solvent SB is preferably 8 to 20, more preferably 10 to 15 in view of affinity for (ease of mixing with) the polymer.

The molecular weight of the solvent SB is preferably 50 to 200, more preferably 70 to 100 from the viewpoint that the viscosity is preferably low.

The viscosity of the solvent SB is preferably 0.01 to 100 mPa·s, more preferably 0.5 to 10 mPa·s.

The evaporation rate index of the solvent SB is preferably 0.1 to 30, more preferably 0.5 to 10.

Examples of the solvent SB include ketone-based, alcohol-based, glycol ether-based, ester-based, and amide-based solvents.

An example of the ketone-based solvent is cyclohexanone (boiling point: 156° C., SP value: 9.6).

Examples of the alcohol-based solvent include ethylene glycol (boiling point: 197° C., SP value: 17.6), propylene glycol (boiling point: 187° C., SP value: 15.4), diacetone alcohol (boiling point: 169° C., SP value: 9.1), 3-methoxy-3-methylbutanol (boiling point: 165° C., SP value: 9.7), and 3-methoxy-1-butanol (boiling point: 161° C., SP value: 10.8).

Examples of the glycol ether-based solvent include propylene glycol mono-n-butyl ether (boiling point: 171° C., SP value: 10.2), dipropylene glycol monomethyl ether (boiling point: 189° C., SP value 10.6), dipropylene glycol dimethyl ether (boiling point: 175° C., SP value: 8.5), propylene glycol monoethyl ether acetate (boiling point: 158° C., SP value: 8.8), ethylene glycol monobutyl ether (boiling point: 171° C., SP value: 10.6), diethylene glycol monobutyl ether (boiling point: 231° C., SP value: 10.4), ethylene glycol monoethyl ether acetate (boiling point: 156° C., SP value: 9.4), ethylene glycol monobutyl ether acetate (boiling point: 188° C., SP value: 8.8), diethylene glycol monobutyl ether acetate (boiling point: 245° C., SP value: 8.9), diethylene glycol dimethyl ether (boiling point: 162° C., SP value: 8.5), diethylene glycol diethyl ether (boiling point: 185° C., SP value: 8.7), and diethylene glycol ethyl methyl ether (boiling point: 179° C., SP value: 8.8).

Examples of the ester-based solvent include butyl lactate (boiling point: 187° C., SP value: 11.1), ethyl 3-ethoxypropionate (boiling point: 170° C., SP value: 9.2), methyl acetoacetate (boiling point: 171° C., SP value: 10.4), ethyl acetoacetate (boiling point: 181° C., SP value: 10.0), gamma-butyrolactone (boiling point: 204° C., SP value: 12.3), and 3-methoxybutyl acetate (boiling point: 173° C., SP value: 9.1).

Examples of the amide-based solvent include N-methylpyrrolidone (boiling point: 204° C., SP value: 11.2) and N,N-dimethylacetamide (boiling point: 165° C., SP value: 10.0).

The solvent SB preferably includes at least one solvent selected from the group consisting of alcohol-based, glycol ether-based, and ester-based solvents, and more preferably includes at least one solvent selected from the group consisting of ethylene glycol, propylene glycol, gamma-butyrolactone, ethyl acetoacetate, dipropylene glycol monomethyl ether, ethylene glycol monobutyl ether acetate, and diethylene glycol diethyl ether.

The difference (T_{SB}-T_{SA}) between the boiling point (T_{SA}) of the solvent SA and the boiling point (T_{SB}) of the solvent SB is preferably 30° C. or more, more preferably 40° C. or more, still more preferably 50° C. or more. When the difference in boiling point is 40° C. or more, the effect of promoting the volatilization of the solvent SA by the solvent SB during drying of the actinic ray-sensitive or radiation-sensitive film is easily obtained. The difference in boiling point is preferably 100° C. or less, more preferably 90° C. or less, still more preferably 80° C. or less. A difference in boiling point of 90° C. or less is preferred because the solvent SB is less likely to remain in the film.

The difference (ΔSP) between the solubility parameter of the solvent SA and the solubility parameter of the solvent SB is preferably 0.01 to 20, more preferably 0.1 to 15, still more preferably 1 to 10.

Note that ΔSP is calculated based on the following formula (spb).

ΔSP=SP value of solvent SB-SP value of solvent SA Formula (spb)

In the composition according to the present invention, the content of the solvent SA is higher than that of the solvent SB, and from the viewpoint of reducing the amount of residual solvent in the film, the content of the solvent SA relative to the whole solvent is preferably 40% by mass or more, more preferably 50% by mass or more, still more preferably 65% by mass or more. The upper limit thereof is preferably 95% by mass or less, more preferably 90% by mass or less, still more preferably 80% by mass or less.

In the composition according to the present invention, the content of the solvent SB is lower than that of the solvent SA, and the content of the solvent SB relative to the whole solvent is 1% to 30% by mass. If the content of the solvent SB is less than 1% by mass, the effect of reducing the amount of residual solvent in the film due to the addition of the solvent SB is less likely to be obtained, and the EL performance becomes poor. On the other hand, if the content exceeds 30% by mass, the amount of the solvent SB remaining in the film increases, and the EL performance also becomes poor. The content of the solvent SB is preferably 5% by mass or more, more preferably 10% by mass or more relative to the whole solvent. The content of the solvent SB is preferably 25% by mass or less, more preferably 20% by mass or less.

### Solvent SC

The solvent (S) may include a solvent (hereinafter, also referred to as another solvent) other than the solvent SA and the solvent SB as long as the effects of the present invention are not impaired, and may include, for example, a solvent SC having a boiling point of 50° C. to 129° C. When the solvent S further includes the solvent SC, a coating film can be formed with a low solid content compared with a solvent having a high boiling point.

The boiling point (T_{SC}) of the solvent SC is more preferably 70° C. to 129° C., still more preferably 100° C. to 129° C.

The solubility parameter (SP value) of the solvent SC is preferably 8 to 20, more preferably 10 to 12 in view of affinity for (ease of mixing with) the polymer.

The molecular weight of the solvent SC is preferably 30 to 150, more preferably 50 to 120 from the viewpoint that the viscosity is preferably low.

The viscosity of the solvent SC is preferably 0.2 to 5 mPa·s, more preferably 0.5 to 2.0 mPa·s.

The evaporation rate index of the solvent SC is preferably 10 to 100, more preferably 50 to 80.

Examples of the solvent SC include aromatic hydrocarbon-based, ketone-based, alcohol-based, glycol ether-based, and ester-based solvents.

An example of the aromatic hydrocarbon-based solvent is toluene (boiling point: 111° C., SP value: 8.6).

Examples of the ketone-based solvent include acetone (boiling point: 56° C., SP value: 8.6), methyl ethyl ketone (boiling point: 80° C., SP value: 8.6), and methyl isobutyl ketone (boiling point: 116° C., SP value: 8.2).

Examples of the alcohol-based solvent include ethanol (boiling point: 78° C., SP value: 12.3) and isopropanol (boiling point: 82° C., SP value: 11.2).

Examples of the glycol ether-based solvent include propylene glycol monomethyl ether (boiling point: 121° C., SP value: 11.2) and ethylene glycol monomethyl ether (boiling point: 124° C., SP value: 12.1).

Examples of the ester-based solvent include ethyl acetate (boiling point: 77° C., SP value: 8.7), butyl acetate (boiling point: 126° C., SP value: 8.5), and isobutyl acetate (boiling point: 117° C., SP value: 8.3).

Other examples include 1,4-dioxane (boiling point: 101° C., SP value: 10.5).

The solvent SC is preferably propylene glycol monomethyl ether, butyl acetate, or ethyl acetate, more preferably propylene glycol monomethyl ether.

When the composition according to the present invention includes a solvent other than the solvent SA and the solvent SB, the content of the other solvent relative to the whole solvent is not limited as long as the effects of the present invention are not inhibited, but is preferably lower than the content of the solvent SA. For example, the content is preferably 1% to 30% by mass, more preferably 5% to 25% by mass.

The content of the solvent (S) in the composition according to the present invention is adjusted so that the concentration of solid contents of the composition according to the present invention is 10% by mass or more. The concentration of solid contents of the composition according to the present invention is 10% by mass or more, and from the viewpoint of providing better effects of the present invention, the concentration of solid contents is preferably 10% to 30% by mass, more preferably 12% to 28% by mass. Note that the concentration of solid contents means a mass percentage of the mass of other components (components that can constitute an actinic ray-sensitive or radiation-sensitive film) excluding the solvents relative to the total mass of the actinic ray-sensitive or radiation-sensitive resin composition.

### Surfactant

The composition according to the present invention may include a surfactant (also referred to as a “surfactant (E)”). When the composition according to the present invention includes a surfactant, a pattern having higher adhesiveness and fewer development defects can be formed.

The surfactant (E) is preferably a fluorine-based surfactant and/or a silicon-based surfactant.

Examples of the fluorine-based surfactant and/or the silicon-based surfactant include the surfactants described in paragraph 0276 of US2008/0248425A. Furthermore, EFTOP EF301 or EF303 (manufactured by Shin-Akita Kasei Co., Ltd.); FLUORAD FC430, 431, or 4430 (manufactured by Sumitomo 3M Limited); MEGAFACE F171, F173, F176, F189, F113, F110, F177, F120, or R08 (manufacturer by DIC Corporation); Surflon S-382, SC101, 102, 103, 104, 105, or 106 (manufacturer by AGC Inc.); Troysol S-366 (manufactured by Troy Chemical Industries, Inc.); GF-300 or GF-150 (manufactured by TOAGOSEI Co., Ltd.); SURFLON S-393 (manufactured by SEIMI CHEMICAL Co., Ltd.); EFTOP EF121, EF122A, EF122B, RF122C, EF125M, EF135M, EF351, EF352, EF801, EF802, or EF601 (manufactured by JEMCO); PF636, PF656, PF6320, or PF6520 (manufactured by OMNOVA Solutions Inc.); KH-20 (manufactured by Asahi Kasei Corporation); or FTX-204G, 208G, 218G, 230G, 204D, 208D, 212D, 218D, or 222D (manufactured by NEOS COMPANY LIMITED) may be used. A polysiloxane polymer KP-341 (manufactured by Shin-Etsu Chemical Co., Ltd.) can also be used as the silicon-based surfactant.

In addition to the publicly known surfactants as described above, the surfactant (E) may be synthesized using a fluoroaliphatic compound produced by a telomerization method (also referred to as a telomer method) or an oligomerization method (also referred to as an oligomer method). Specifically, a polymer including a fluoroaliphatic group derived from the fluoroaliphatic compound may be used as the surfactant. The fluoroaliphatic compound can be synthesized by, for example, the method described in JP2002-90991A.

The polymer having a fluoroaliphatic group is preferably a copolymer of a monomer having a fluoroaliphatic group and a (poly(oxyalkylene)) acrylate and/or a (poly(oxyalkylene)) methacrylate, which may be randomly distributed or block-copolymerized. The poly(oxyalkylene) group may be a poly(oxyethylene) group, a poly(oxypropylene) group, or a poly(oxybutylene) group, and may be a unit having alkylenes with different chain lengths in the same chain, such as poly(block linkage of oxyethylene, oxypropylene, and oxyethylene) and poly(block linkage of oxyethylene and oxypropylene). Furthermore, the copolymer of a monomer having a fluoroaliphatic group and a (poly(oxyalkylene)) acrylate (or methacrylate) is not limited to a binary copolymer, and may be a ternary or higher copolymer obtained by simultaneously copolymerizing two or more different monomers having a fluoroaliphatic group, two or more different (poly(oxyalkylene)) acrylates (or methacrylates), and the like.

Examples of commercially available surfactants include MEGAFACE F178, F-470, F-473, F-475, F-476, and F-472 (manufactured by DIC Corporation), copolymers of an acrylate (or methacrylate) having a C₆F₁₃ group and (poly(oxyalkylene)) acrylates (or methacrylates), and copolymers of an acrylate (or methacrylate) having a C₃F₇ group, (poly(oxyethylene)) acrylates (or methacrylates), and (poly(oxypropylene)) acrylates (or methacrylates).

Surfactants other than fluorine-based and/or silicon-based surfactants, described in paragraph [0280] of US2008/0248425A may be used.

Such surfactants (E) may be used alone or in combination of two or more thereof.

The composition according to the present invention may or may not contain the surfactant (E). When the composition according to the present invention contains the surfactant (E), the content of the surfactant (E) is preferably 0.0001% to 2% by mass, more preferably 0.0005% to 1% by mass relative to the total solid content of the composition according to the present invention.

### Hydrophobic Resin

The composition according to the present invention may include a hydrophobic resin (also referred to as a “hydrophobic resin (F)”).

The hydrophobic resin (F) is a resin that is hydrophobic and different from the resin (A) described above.

The hydrophobic resin (F) is preferably designed so as to be localized in the surface of the actinic ray-sensitive or radiation-sensitive film; however, unlike surfactants, the hydrophobic resin (F) is not necessarily required to have a hydrophilic group in the molecule and does not necessarily contribute to homogeneous mixing of a polar substance and a nonpolar substance.

Advantages due to the addition of the hydrophobic resin (F) may be the control of static and dynamic contact angles at the surface of the actinic ray-sensitive or radiation-sensitive film with respect to water and the suppression of outgassing.

The hydrophobic resin (F) preferably has any one or more, more preferably two or more, selected from the group consisting of “a fluorine atom”, “a silicon atom”, and “a CH₃ moiety included in a side chain moiety of the resin” from the viewpoint of localization in the surface layer of the film. The hydrophobic resin (F) preferably has a hydrocarbon group having 5 or more carbon atoms. The resin may have such a group in the main chain thereof or, as a substituent, in a side chain thereof.

When the hydrophobic resin (F) includes a fluorine atom and/or a silicon atom, the fluorine atom and/or the silicon atom in the hydrophobic resin may be included in the main chain of the resin or may be included in a side chain.

When the hydrophobic resin (F) has a fluorine atom, a fluorine atom-containing moiety is preferably a fluorine atom-containing alkyl group, a fluorine atom-containing cycloalkyl group, or a fluorine atom-containing aryl group.

The fluorine atom-containing alkyl group (preferably having 1 to 10 carbon atoms and more preferably having 1 to 4 carbon atoms) is a linear or branched alkyl group in which at least one hydrogen atom is substituted with a fluorine atom, and may further have a substituent other than the fluorine atom.

The fluorine atom-containing cycloalkyl group is a monocyclic or polycyclic cycloalkyl group in which at least one hydrogen atom is substituted with a fluorine atom, and may further have a substituent other than the fluorine atom.

The fluorine atom-containing aryl group may be a fluorine atom-containing aryl group in which at least one hydrogen atom of an aryl group, such as a phenyl group or a naphthyl group, is substituted with a fluorine atom, and may further have a substituent other than the fluorine atom.

Examples of a repeating unit having a fluorine atom or a silicon atom include those exemplified in paragraph 0519 of US2012/0251948A.

As described above, it is also preferable that the hydrophobic resin (F) have a CH₃ moiety in a side chain moiety.

Herein, the CH₃ moiety in a side chain moiety in the hydrophobic resin includes CH₃ moieties having an ethyl group, a propyl group, or the like.

On the other hand, a methyl group directly bonded to the main chain of the hydrophobic resin (F) (for example, an α-methyl group of a repeating unit having a methacrylic acid structure) has a small contribution to the surface localization of the hydrophobic resin (F) due to the influence of the main chain, and therefore is not included in the CH₃ moiety in the present invention.

Regarding the hydrophobic resin (F), the description in paragraphs 0348 to 0415 of JP2014-010245A can be referred to, and the contents thereof are incorporated herein by reference.

As the hydrophobic resin (F), resins described in JP2011-248019A, JP2010-175859A, and JP2012-032544A also can be preferably used.

The composition according to the present invention may or may not contain the hydrophobic resin (F). When the composition according to the present invention contains the hydrophobic resin (F), the content of the hydrophobic resin (F) is preferably 0.01% to 20% by mass, more preferably 0.1% to 15% by mass relative to the total solid content of the composition according to the present invention.

### Vinyl Group-Containing Compound

The composition according to the present invention may further contain a vinyl group-containing compound (G).

The vinyl group-containing compound is a polyfunctional vinyl ether compound containing two or more vinyl ether groups in which oxygen atoms of vinyloxy groups (CH₂═CH—O—) are bonded to carbon atoms.

When the composition according to the present invention contains the vinyl group-containing compound (G), a pattern of a thick-film resist having good crack resistance can be formed.

The number of vinyl ether groups is not particularly limited, but is preferably 2 or more.

The number of vinyl ether groups is not particularly limited, but is preferably 10 or less.

The number of vinyl ether groups is not particularly limited, but is preferably 2 or 3, more preferably 2.

The molecular weight of the vinyl group-containing compound (G) is not particularly limited, but is preferably 50 to 500, more preferably 100 to 300.

It is presumed that the vinyl group-containing compound acts as a crosslinking agent for the component (A) described above to exhibit the following effects.

It is presumed that the vinyl group-containing compound undergoes a crosslinking reaction with the component (A) due to heating during prebaking and can form a film in which the weight-average molecular weight of the component (A) is increased, thereby exhibiting the effect of crack resistance. In addition, after the alkali-insolubilized resist layer is formed over the entire surface of a substrate, the crosslinking is decomposed by the action of acid generated from the photoacid generator (C) upon exposure, exposed portions are changed to be alkali-soluble, and non-exposed portions remain alkali-insoluble, so that patterning can be performed while crack resistance is maintained.

On the other hand, the vinyl group-containing compound has a property of being localized in the surface of a resist film by moving in the film if a predetermined amount of solvent remains in the resist film at the time of heating during prebaking. If the vinyl group-containing compound cannot be present homogeneously in the film, the crosslinking reaction does not proceed homogeneously, and desired crack resistance tends not to be exhibited.

When the difference (T_{SB}-T_{SA}) between the boiling point (T_{SA}) of the solvent SA and the boiling point (T_{SB}) of the solvent SB is 40° C. or more, the effect of promoting the volatilization of the solvent SA by the solvent SB during drying of the actinic ray-sensitive or radiation-sensitive film is easily obtained, and the vinyl group-containing compound can be homogeneously dispersed in the film. The homogeneously dispersed vinyl group-containing compound enables desired crack resistance to be exhibited.

Regarding details of the vinyl group-containing compound, compounds described in paragraphs [0163] to [0173] of JP2021-131530A can be used, and, specifically, examples thereof include the following compounds.

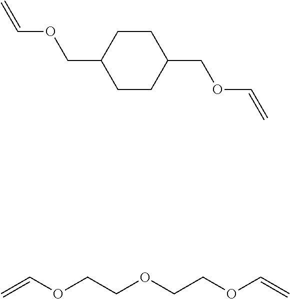

The composition according to the present invention may or may not contain the vinyl group-containing compound (G). When the composition according to the present invention contains the vinyl group-containing compound (G), the content of the vinyl group-containing compound (G) is preferably 0.01% to 10% by mass, more preferably 0.1% to 7% by mass relative to the total solid content of the composition according to the present invention.

In the composition according to the present invention, a resin obtained by causing the component (A) and the vinyl group-containing compound to react with each other may also be used.

When the component (A) and the vinyl group-containing compound are caused to react with each other, a crosslinking reaction proceeds to obtain a resin in which the components (A) are bonded to each other through a cross-linking group.

Since the obtained resin has an acid-decomposable group in the cross-linking group, the crosslinking is decomposed by the action of acid generated from the photoacid generator (C) upon exposure, so that exposed portions are changed to be alkali-soluble and non-exposed portions remain alkali-insoluble. As described above, patterning can be performed while crack resistance is maintained as in the case where the composition according to the present invention contains the component (A) and the component (G).

### Other Components

The composition according to the present invention may contain other components other than the components described above. Examples of the other components include crosslinking agents, alkali-soluble resins, dissolution inhibiting compounds, dyes, plasticizers, photosensitizers, light absorbents, and compounds that improve solubility in developers.

### Viscosity

The viscosity of the composition according to the present invention is not particularly limited, but is preferably 10 to 100 mPa·s, more preferably 15 to 90 mPa·s, still more preferably 30 to 70 mPa·s at 25° C. The viscosity of the actinic ray-sensitive or radiation-sensitive resin composition is determined by conducting measurement at 25° C. using an E-type viscometer (Model RE-85L, manufactured by Toki Sangyo Co., Ltd.).

### Preparation Method

The composition according to the present invention can be prepared by dissolving the resin (A), the photoacid generator (C), and the optional above-described components in the solvent (S), and filtering the resulting solution through a filter. The solvent (S) can be prepared by mixing the solvent SA, the solvent SB, and another optional solvent such as the solvent SC. The solvent (S) may be prepared before mixing with each component other than the solvents, or may be prepared simultaneously with the mixing.

The pore size of the filter used for filter filtration is not particularly limited, but is preferably 3 m or less, more preferably 0.5 m or less, still more preferably 0.3 m or less. In some cases, it is also preferable that the pore size of the filter be 0.1 m or less, 0.05 m or less, and 0.03 m or less. The filter is preferably formed of polytetrafluoroethylene, polyethylene, or nylon. In filter filtration, for example, as disclosed in JP2002-62667A, circulation filtration may be performed, or filtration may be performed by connecting a plurality of types of filters in series or in parallel. The composition may be filtered multiple times. Furthermore, the composition may be subjected to, for example, deaeration treatment before or after the filter filtration.

### Applications

The composition according to the present invention reacts upon irradiation with an actinic ray or radiation to undergo a change in a property. The composition according to the present invention can be used for a step of producing a semiconductor such as an integrated circuit (IC), production of a circuit board for, for example, liquid crystal or a thermal head, production of an imprint mold structure, another photofabrication step, or production of a planographic plate or an acid-curable composition, for example. A pattern formed using the composition according to the present invention can be used in an etching step, an ion implanting step, a bump electrode formation step, a redistribution formation step, and micro electro mechanical systems (MEMS), for example.

### Pattern Forming Method and Actinic Ray-Sensitive or Radiation-Sensitive Film

A pattern forming method according to the present invention has
a step of forming, on a substrate, an actinic ray-sensitive or radiation-sensitive film (preferably a resist film) using the actinic ray-sensitive or radiation-sensitive resin composition according to the present invention;
a step of exposing the actinic ray-sensitive or radiation-sensitive film to obtain an exposed actinic ray-sensitive or radiation-sensitive film; and
a step of, using a developer, developing the exposed actinic ray-sensitive or radiation-sensitive film to form a pattern.

Hereinafter, each of the steps will be described in detail.

### Step a: Actinic Ray-Sensitive or Radiation-Sensitive Film Formation Step

A step a is a step of forming, on a substrate, an actinic ray-sensitive or radiation-sensitive film using the composition according to the present invention.

An example of the method for forming, on a substrate, an actinic ray-sensitive or radiation-sensitive film using the composition according to the present invention is a method of applying the composition according to the present invention onto a substrate.

The composition according to the present invention can be applied onto a substrate (for example, formed of silicon and covered with silicon dioxide) as used in the production of an integrated circuit element by a suitable coating method using a spinner, a coater, or the like. The coating method is preferably spin-coating using a spinner.

After the application of the composition according to the present invention, the substrate may be dried to form an actinic ray-sensitive or radiation-sensitive film. Note that, as needed, as underlayers of the actinic ray-sensitive or radiation-sensitive film, various underlying films (an inorganic film, an organic film, or an antireflection film) may be formed.

The drying method is, for example, a method of heating (prebaking: PB). The heating can be performed using means included in an ordinary exposure device and/or an ordinary development device, or may be performed using a hot plate, for example.

The heating temperature is preferably 80° C. to 150° C., more preferably 80° C. to 140° C.

The heating time is preferably 30 to 1,000 seconds, more preferably 40 to 800 seconds.

The film thickness of the actinic ray-sensitive or radiation-sensitive film is not particularly limited.

When the actinic ray-sensitive or radiation-sensitive film is an actinic ray-sensitive or radiation-sensitive film for KrF exposure, the film thickness is preferably 500 nm or more, more preferably 800 nm or more and 12 m or less, still more preferably 1 m or more and 6 m or less.

When the actinic ray-sensitive or radiation-sensitive film is an actinic ray-sensitive or radiation-sensitive film for ArF exposure or EUV exposure, the film thickness is preferably 10 to 700 nm, more preferably 20 to 400 nm.

The present invention also relates to an actinic ray-sensitive or radiation-sensitive film formed from the composition according to the present invention. When the film thickness of the actinic ray-sensitive or radiation-sensitive film is 500 nm or more, an advantage of the present invention that a pattern having a good EL performance can be formed is remarkably exhibited.

As an overlying layer of the actinic ray-sensitive or radiation-sensitive film, a topcoat may be formed using a topcoat composition.

Preferably, the topcoat composition does not mix with the actinic ray-sensitive or radiation-sensitive film and further can be uniformly applied as an overlying layer of the actinic ray-sensitive or radiation-sensitive film.

The film thickness of the topcoat is preferably 10 to 200 nm, more preferably 20 to 100 nm.

The topcoat is not particularly limited, and a publicly known topcoat can be formed by a publicly known method. For example, a topcoat can be formed on the basis of the description of paragraphs 0072 to 0082 of JP2014-059543A.

### Step b: Exposure Step

A step b is a step of exposing the actinic ray-sensitive or radiation-sensitive film to obtain an exposed actinic ray-sensitive or radiation-sensitive film.

An example of the exposure method may be a method of applying an actinic ray or radiation either through a mask disposed between a light source and an actinic ray-sensitive or radiation-sensitive film or without disposing a mask directly.

Examples of the actinic ray or radiation include infrared light, visible light, ultraviolet light, far-ultraviolet light, extreme ultraviolet light, X-rays, and electron beams (EB). For example, KrF excimer laser (248 nm), ArF excimer laser (193 nm), F₂ excimer laser (157 nm), EUV (13 nm), X-rays, and EB are preferred.

The light source for exposure in the step b is particularly preferably KrF.

After the exposure and before development, baking (post-exposure baking: PEB) is preferably performed.

The heating temperature is preferably 80° C. to 150° C., more preferably 80° C. to 140° C.

The heating time is preferably 10 to 1,000 seconds, more preferably 10 to 180 seconds.

The heating can be performed using means included in an ordinary exposure device and/or an ordinary development device, or may be performed using a hot plate, for example.

This step is also referred to as post-exposure baking.

### Step c: Development Step

A step c is a step of, using a developer, developing the exposed actinic ray-sensitive or radiation-sensitive film to form a pattern.

Examples of the development method include a method of immersing, for a predetermined time, the substrate in a tank filled with the developer (dipping method), a method of puddling the developer on the surface of the substrate using surface tension and leaving the developer at rest for a predetermined time to perform development (puddling method), a method of spraying the developer onto the surface of the substrate (spraying method), and a method of continuously ejecting the developer while scanning, at a constant rate, a developer jetting nozzle over the substrate rotated at a constant rate (dynamic dispensing method).

After the step of performing development, a step of stopping the development while performing replacement with another solvent may be performed.

The development time is not particularly limited as long as the resin in the non-exposed portions is sufficiently dissolved within the time, and is preferably 10 to 300 seconds, more preferably 20 to 120 seconds.

The temperature of the developer is preferably 0° C. to 50° C., more preferably 15° C. to 35° C.

Examples of the developer include alkali developers and organic solvent developers.

As the alkali developer, an alkali aqueous solution including an alkali is preferably used. In particular, the alkali developer is preferably an aqueous solution of a quaternary ammonium salt represented by tetramethylammonium hydroxide (TMAH). An appropriate amount of an alcohol, a surfactant, or the like may be added to the alkali developer. The alkali developer ordinarily has an alkali concentration of 0.1% to 20% by mass. The alkali developer ordinarily has a pH of 10.0 to 15.0.

The organic solvent developer is a developer including an organic solvent.

Examples of the organic solvent used in the organic solvent developer include publicly known organic solvents, such as ester-based solvents, ketone-based solvents, alcohol-based solvents, amide-based solvents, ether-based solvents, and hydrocarbon-based solvents.

### Other Steps

The pattern forming method according to the present invention may include a step of, after the step c, using a rinsing liquid to perform rinsing.

After the development step using an alkali developer, the rinsing liquid used in the rinsing step may be, for example, pure water. An appropriate amount of surfactant may be added to the rinsing liquid.

After the development step using an organic-based developer, the rinsing liquid used in the rinsing step is not particularly limited as long as the rinsing liquid does not dissolve the resist pattern, and may be a solution including a common organic solvent. A rinsing liquid containing at least one organic solvent selected from the group consisting of hydrocarbon-based solvents, ketone-based solvents, ester-based solvents, alcohol-based solvents, amide-based solvents, and ether-based solvents is preferably used as the rinsing liquid. An appropriate amount of surfactant may be added to the rinsing liquid.

The formed pattern may be used as a mask to perform etching treatment of the substrate. Specifically, the pattern formed in the step c may be used as a mask to process the substrate (or the underlayer film and the substrate), thereby forming a pattern in the substrate.

The method of processing the substrate (or the underlayer film and the substrate) is not particularly limited, but is preferably a method of subjecting the substrate (or the underlayer film and the substrate) to dry etching using the pattern formed in the step c as a mask, thereby forming a pattern in the substrate.

The dry etching may be a single-step etching or a multi-step etching. When the etching is performed in multiple steps, the etching treatment in each step may be the same or different.

For the etching, any publicly known method may be used, and various conditions and the like are appropriately determined depending on, for example, the type or use of the substrate. For example, the etching can be carried out in accordance with, for example, Proceedings of International Society for Optics and Photonics (Proc. of SPIE), Vol. 6924, 692420 (2008) and JP2009-267112A. The etching may also be carried out in accordance with the method described in “Chapter 4, Etching” of “Semiconductor Process Textbook, 4th edition, issued in 2007, publisher: SEMI Japan”.

The dry etching is preferably oxygen plasma etching.

Various materials used in the present invention (for example, the solvent, the developer, the rinsing liquid, the antireflection film-forming composition, and the topcoat-forming composition) preferably do not include impurities such as metal. The content of impurities included in such materials is preferably 1 mass ppm (parts per million) or less, more preferably 10 mass ppb (parts per billion) or less, still more preferably 100 mass ppt (parts per trillion) or less, particularly preferably 10 mass ppt or less, most preferably 1 mass ppt or less. Examples of metal impurities include Na, K, Ca, Fe, Cu, Mn, Mg, Al, L₁, Cr, Ni, Sn, Ag, As, Au, Ba, Cd, Co, Mo, Zr, Pb, Ti, V, W, and Zn.

The method for removing impurities, such as metal, from the various materials may be, for example, filtration using a filter. The filter pore diameter is preferably 0.20 m or less, more preferably 0.05 m or less, still more preferably 0.01 m or less.

As the material of the filter, fluororesins such as polytetrafluoroethylene (PTFE) and perfluoroalkoxy alkanes (PFA), polyolefin resins such as polypropylene and polyethylene, and polyamide resins such as nylon 6 and nylon 66 are preferred. The filter may be washed with an organic solvent in advance and used. In the filter filtration step, a plurality of filters or a plurality of types of filters may be connected in series or in parallel and used. When a plurality of types of filters are used, filters having different pore diameters and/or composed of different materials may be used in combination. The various materials may be filtered a plurality of times, and the step of performing filtration a plurality of times may be a circulation filtration step. The circulation filtration step is preferably, for example, a method disclosed in JP2002-62667A.

The filter is preferably a filter in which an eluted substance is reduced as disclosed in JP2016-201426A.

Instead of filter filtration, an adsorbing material may be used to remove impurities. Alternatively, filter filtration and an adsorbing material may be used in combination. Publicly known adsorbing materials can be used as such adsorbing materials, and, for example, an inorganic adsorbing material such as silica gel or zeolite, or an organic adsorbing material such as activated carbon can be used. Examples of metal adsorbents include those disclosed in JP2016-206500A.

Examples of the method of reducing the amount of impurities such as metal included in the various materials include a method of selecting, as raw materials constituting the various materials, raw materials having low metal contents, a method of subjecting raw materials constituting the various materials to filter filtration, and a method of performing distillation under conditions in which contamination is minimized by, for example, lining or coating the interior of the apparatus with a fluororesin or the like. Preferred conditions for the filter filtration performed for the raw materials constituting the various materials are the same as those described above.

The above various materials are preferably stored in containers described in, for example, US2015/0227049A, JP2015-123351A, or JP2017-13804A in order to prevent the entry of contamination.

The various materials may be diluted with a solvent used in the composition and then used.

### Method for Producing Electronic Device

The present invention also relates to a method for producing an electronic device, the method including the above-described pattern forming method.

The electronic device according to the present invention is suitably mounted on electric or electronic devices (such as household appliances, office automation (OA), media-related devices, optical devices, and communication devices).

### Examples

Hereinafter, the present invention will be described in more detail with reference to Examples. Materials, amounts used, ratios, details of treatment, orders of treatments, and the like described in the following Examples can be appropriately changed without departing from the spirit and scope of the present invention. The scope of the present invention is not construed as being limited to the following Examples.

### Resin (A)

The following acid-decomposable resins were used as the resin (A).

The number-average molecular weight (Mn), the weight-average molecular weight (Mw), and the molecular weight distribution (Mw/Mn) of each resin were measured by the methods described above. The compositional ratio of the repeating units in each resin (contents relative to all the repeating units in the resin) (unit: mol %) was measured by ¹³C-NMR (nuclear magnetic resonance).

Table 1 shows the compositional ratio of repeating units in each resin, and the weight-average molecular weight and the molecular weight distribution of each resin.

The repeating units in each resin are described as a repeating unit 1, a repeating unit 2, and a repeating unit 3 in order from the left repeating unit.

TABLE 1

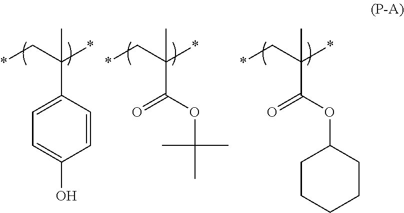

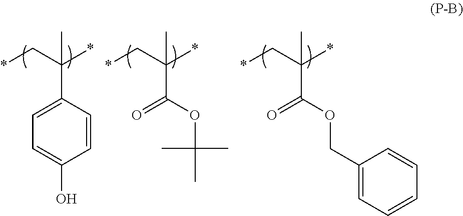

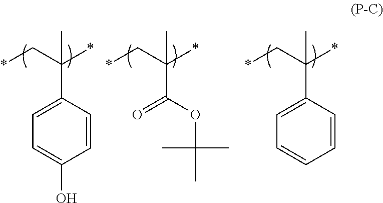

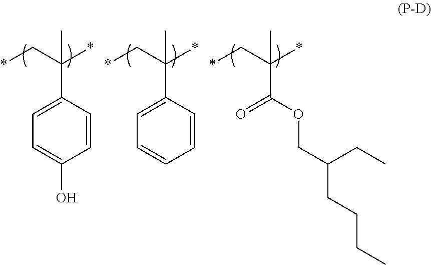

| | | | | Weight-average | Molecular |
|---|---|---|---|---|---|
| | | | | molecular | weight |
| Resin | Repeating unit 1 | Repeating unit 2 | Repeating unit 3 | weight | distribution |
| (A) | (mol%) | (mol%) | (mol%) | (Mw) | (Mw/Mn) |
| P-A | 65 | 25 | 10 | 26,000 | 1.5 |
| P-B | 65 | 25 | 10 | 22,000 | 1.8 |
| P-C | 65 | 20 | 15 | 25,000 | 1.8 |
| P-D | 63 | 18 | 19 | 21,000 | 1.5 |

### Photoacid Generator (C)

The structures of compounds used as the photoacid generator are shown below.

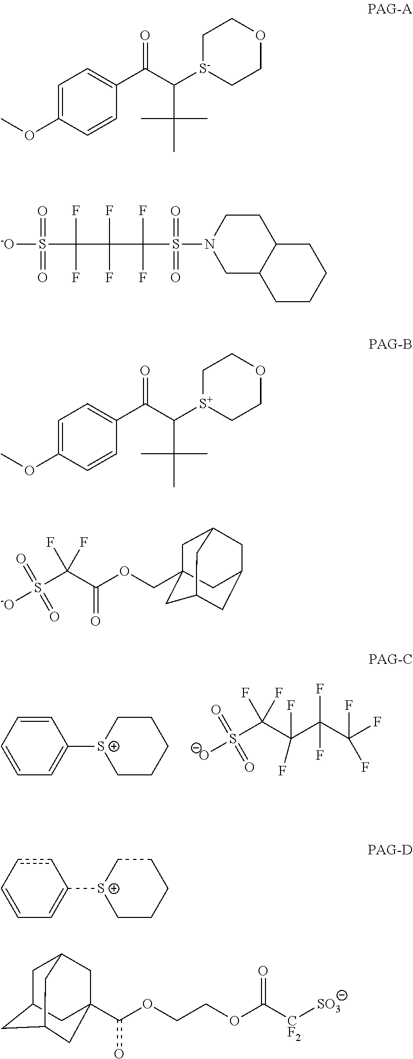

### Acid Diffusion Control Agent (D)

The structures of compounds used as the acid diffusion control agent are shown below.

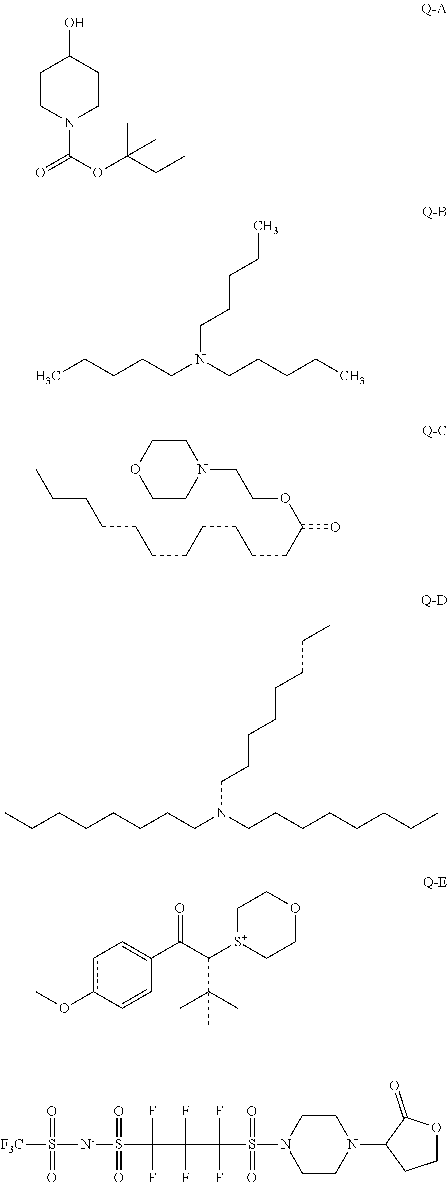

### Hydrophobic Resin

The following F-A and F—B were used as the hydrophobic resin. The content ratio of each repeating unit (content relative to all repeating units in the resin) is the molar ratio.

Table 2 shows the weight-average molecular weight and the molecular weight distribution of each hydrophobic resin.

TABLE 2

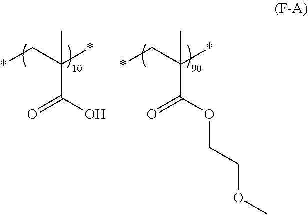

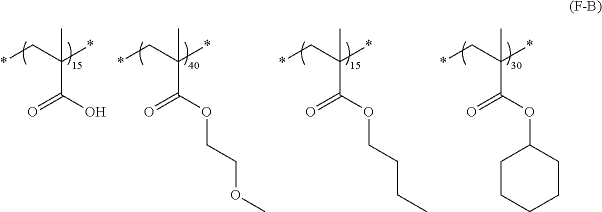

| | Weight-average | Molecular weight |
|---|---|---|
| | molecular weight | distribution |
| F-A | 5,000 | 5.0 |
| F-B | 8,000 | 5.0 |

### Surfactant

The following W-A to W-C were used as the surfactant.
W-A: TF-R41 (manufacturer by DIC Corporation)
W-B: MEGAFACE R40 (manufacturer by DIC Corporation)
W-C: MEGAFACE F-576 (manufacturer by DIC Corporation)

### Solvent (S)

The following are solvents used in Examples. Numerical values in parentheses indicate boiling points.

### Solvent SA

PGMEA: Propylene glycol monomethyl ether acetate (146° C.)
Methyl lactate (145° C.)
Propylene glycol monoethyl ether (133° C.)
Methyl 3-methoxypropionate (142° C.)

### Solvent SB

gamma-Butyrolactone (204° C.)
Ethylene glycol monobutyl ether acetate (188° C.)
Ethyl 3-ethoxypropionate (170° C.)
N-Methylpyrrolidone (204° C.)
N,N-Dimethylacetamide (165° C.)

### Solvent SC

PGME: Propylene glycol monomethyl ether (121° C.)
Butyl acetate (126° C.)
Ethyl acetate (77° C.)

The following are solvents other than the above and used in Comparative Examples. Numerical values in parentheses indicate boiling points.
Ethyl lactate (154° C.)
1,4-Dioxane (104° C.)
Dibutyl ether (142° C.)
Tetraethylene glycol (275° C.)

### Preparation of Resist Composition

Resist compositions R-1 to R-22 and RX-1 to RX-8 were each obtained by dissolving the components shown in Table 3 below in the solvents shown in Table 3 to prepare a solution having the concentration of solid contents shown in Table 3, and filtering the solution through a polyethylene filter having a pore size of 3 m.

The solid content means all components other than the solvents. The obtained resist compositions were used in Examples and Comparative Examples.

The content of each component in Table 3 is a ratio based on mass relative to the total solid content of each resist composition. The “%” is based on the mass (that is, “mass %”). The concentration of solid contents means a mass percentage of the mass of other components excluding the solvents relative to the total mass of each resist composition.

As the solvent (S), the compounds shown in Table 3 were used at the mass ratios shown in Table 3.

In Example 16, two compounds were used as the photoacid generator (C) at the mass ratio shown in Table 3. In Examples 1 to 8, 10, 11, and 14 to 22 and Comparative Examples 1 to 6 and 8, two compounds were used as the acid diffusion control agent (D) at the “mass %” shown in Table 3.

Table 3 also shows the mass ratio of the solvent SB to the photoacid generator (C) (solvent SB/photoacid generator (C)).

TABLE 3

| | | Composition | | | | | | | | | |
|---|---|---|---|---|---|---|---|---|---|---|---|
| | | | | Photoacid generator | | | | | | | |
| | | Resin (A) | | (C) | | Acid diffusion control | | Hydrophobic resin | | Surfactant | |
| | | | Content | | Content | agent (D) | | | Content | | Content |
| | Com- | | [mass | | [mass | | Content | | [mass | | [mass |
| | position | Type | %] | Type | %] | Type | [mass %] | Type | %] | Type | %] |
| Example | R-1 | P-A | 92.320 | PAG-A | 7.20 | Q-A/Q-E | 0.235/0.160 | — | — | W-A | 0.085 |
| 1 | | | | | | | | | | | |
| Example | R-2 | P-A | 92.251 | PAG-A | 7.26 | Q-A/Q-E | 0.247/0.157 | — | — | W-A | 0.085 |
| 2 | | | | | | | | | | | |
| Example | R-3 | P-A | 91.993 | PAG-A | 7.50 | Q-A/Q-E | 0.269/0.153 | — | — | W-A | 0.085 |
| 3 | | | | | | | | | | | |
| Example | R-4 | P-A | 91.605 | PAG-A | 7.90 | Q-A/Q-E | 0.259/0.151 | — | — | W-A | 0.085 |
| 4 | | | | | | | | | | | |
| Example | R-5 | P-A | 91.713 | PAG-A | 7.80 | Q-A/Q-E | 0.250/0.152 | — | — | W-A | 0.085 |
| 5 | | | | | | | | | | | |
| Example | R-6 | P-A | 92.143 | PAG-A | 7.35 | Q-A/Q-E | 0.269/0.153 | — | — | W-A | 0.085 |
| 6 | | | | | | | | | | | |
| Example | R-7 | P-A | 98.893 | PAG-A | 0.60 | Q-A/Q-E | 0.269/0.153 | — | — | W-A | 0.085 |
| 7 | | | | | | | | | | | |
| Example | R-8 | P-B | 91.967 | PAG-B | 7.50 | Q-A/Q-E | 0.293/0.155 | — | — | W-A | 0.085 |
| 8 | | | | | | | | | | | |
| Example | R-9 | P-C | 97.715 | PAG-C | 2.00 | Q-B | 0.200 | — | — | W-A | 0.085 |
| 9 | | | | | | | | | | | |
| Example | R-10 | P-D | 91.713 | PAG-A | 7.80 | Q-A/Q-E | 0.250/0.152 | — | — | W-A | 0.085 |
| 10 | | | | | | | | | | | |
| Example | R-11 | P-A | 91.713 | PAG-A | 7.80 | Q-A/Q-E | 0.250/0.152 | — | — | W-A | 0.085 |
| 11 | | | | | | | | | | | |
| Example | R-12 | P-C | 92.143 | PAG-D | 7.35 | Q-B | 0.269 | F-A | 0.153 | W-B | 0.085 |
| 12 | | | | | | | | | | | |
| Example | R-13 | P-C | 91.993 | PAG-D | 7.50 | Q-B | 0.269 | F-B | 0.153 | W-B | 0.085 |
| 13 | | | | | | | | | | | |
| Example | R-14 | P-A | 92.033 | PAG-A | 7.46 | Q-C/Q-E | 0.269/0.153 | — | — | W-C | 0.085 |
| 14 | | | | | | | | | | | |
| Example | R-15 | P-B | 92.143 | PAG-B | 7.35 | Q-D/Q-E | 0.269/0.153 | — | — | W-C | 0.085 |
| 15 | | | | | | | | | | | |
| Example | R-16 | P-A | 92.253 | PAG-A/ | 3.63/ | Q-A/Q-E | 0.250/0.152 | — | — | W-A | 0.085 |
| 16 | | | | PAG-C | 3.63 | | | | | | |
| Example | R-17 | P-A | 92.012 | PAG-A | 7.50 | Q-A/Q-E | 0.250/0.153 | — | — | W-A | 0.085 |
| 17 | | | | | | | | | | | |
| Example | R-18 | P-A | 91.893 | PAG-A | 7.60 | Q-B/Q-E | 0.269/0.153 | — | — | W-A | 0.085 |
| 18 | | | | | | | | | | | |
| Example | R-19 | P-A | 92.392 | PAG-A | 7.12 | Q-C/Q-E | 0.250/0.153 | — | — | W-C | 0.085 |
| 19 | | | | | | | | | | | |
| Example | R-20 | P-A | 92.143 | PAG-B | 7.35 | Q-D/Q-E | 0.269/0.153 | — | — | W-B | 0.085 |
| 20 | | | | | | | | | | | |
| Example | R-21 | P-A | 91.961 | PAG-A | 7.55 | Q-A/Q-E | 0.247/0.157 | — | — | W-A | 0.085 |
| 21 | | | | | | | | | | | |
| Example | R-22 | P-A | 92.055 | PAG-B | 7.45 | Q-C/Q-E | 0.253/0.157 | — | — | W-A | 0.085 |
| 22 | | | | | | | | | | | |
| | | Composition | | | | | | | | | |
| | | | | | | | | | Solvent | | |
| | | Solvent SA | | Solvent SB | | Solvent SC | | Solvent | SB/ | | |
| | | | Boiling | | Boiling | | Boiling | ratio | Photoacid | Solid | |
| | Com- | | point | | point | | point | SA/SB/ | generator | content | |
| | position | Type | (° C.) | Type | (° C.) | Type | (° C.) | SC | (C) | [mass %] | |
| Example | R-1 | PGMEA | 146 | gamma- | 204 | — | — | 80/20/0 | 15 | 15.8 | |
| 1 | | | | Butyrolactone | | | | | | | |
| Example | R-2 | PGMEA | 146 | gamma- | 204 | PGME | 121 | 70/10/20 | 7 | 16.1 | |
| 2 | | | | Butyrolactone | | | | | | | |
| Example | R-3 | PGMEA | 146 | Ethylene glycol | 188 | PGME | 121 | 70/10/20 | 7 | 15.9 | |
| 3 | | | | monobutyl ether | | | | | | | |
| | | | | acetate | | | | | | | |
| Example | R-4 | PGMEA | 146 | Ethyl 3- | 170 | PGME | 121 | 70/10/20 | 7 | 15.8 | |
| 4 | | | | ethoxypropionate | | | | | | | |
| Example | R-5 | PGMEA | 146 | N- | 204 | PGME | 121 | 70/10/20 | 7 | 15.7 | |
| 5 | | | | Methylpyrrolidone | | | | | | | |
| Example | R-6 | PGMEA | 146 | N,N- | 165 | PGME | 121 | 70/10/20 | 7 | 15.9 | |
| 6 | | | | Dimethylacetamide | | | | | | | |
| Example | R-7 | PGMEA | 146 | gamma- | 204 | PGME | 121 | 55/25/20 | 220 | 15.9 | |
| 7 | | | | Butyrolactone | | | | | | | |
| Example | R-8 | PGMEA | 146 | gamma- | 204 | PGME | 121 | 70/10/20 | 7 | 15.9 | |
| 8 | | | | Butyrolactone | | | | | | | |
| Example | R-9 | PGMEA | 146 | gamma- | 204 | PGME | 121 | 70/10/20 | 53 | 16.0 | |
| 9 | | | | Butyrolactone | | | | | | | |
| Example | R-10 | PGMEA | 146 | gamma- | 204 | PGME | 121 | 70/10/20 | 7 | 15.7 | |
| 10 | | | | Butyrolactone | | | | | | | |
| Example | R-11 | Methyl lactate | 145 | gamma- | 204 | PGME | 121 | 70/10/20 | 7 | 15.7 | |
| 11 | | | | Butyrolactone | | | | | | | |
| Example | R-12 | PGMEA | 146 | gamma- | 204 | PGME | 121 | 70/10/20/ | 7 | 15.9 | |
| 12 | | | | Butyrolactone | | | | | | | |
| Example | R-13 | PGMEA | 146 | gamma- | 204 | PGME | 121 | 70/10/20 | 7 | 15.9 | |
| 13 | | | | Butyrolactone | | | | | | | |
| Example | R-14 | PGMEA | 146 | gamma- | 204 | PGME | 121 | 70/10/20 | 7 | 15.9 | |
| 14 | | | | Butyrolactone | | | | | | | |
| Example | R-15 | PGMEA | 146 | gamma- | 204 | PGME | 121 | 65/15/20 | 11 | 15.9 | |
| 15 | | | | Butyrolactone | | | | | | | |
| Example | R-16 | PGMEA | 146 | gamma- | 204 | PGME | 121 | 70/10/20 | 7 | 15.8 | |
| 16 | | | | Butyrolactone | | | | | | | |
| Example | R-17 | Propylene glycol | 133 | gamma- | 204 | PGME | 121 | 70/10/20 | 7 | 15.5 | |
| 17 | | monomethyl | | Butyrolactone | | | | | | | |
| | | ether | | | | | | | | | |
| Example | R-18 | Methyl 3- | 142 | gamma- | 204 | PGME | 121 | 70/10/20 | 7 | 15.9 | |
| 18 | | methoxy- | | Butyrolactone | | | | | | | |
| | | propionate | | | | | | | | | |
| Example | R-19 | PGMEA | 146 | gamma- | 204 | Butyl | 126 | 70/10/20 | 7 | 16.0 | |
| 19 | | | | Butyrolactone | | acetate | | | | | |
| Example | R-20 | PGMEA | 146 | gamma- | 204 | Ethyl | 77 | 70/10/20 | 7 | 16.1 | |
| 20 | | | | Butyrolactone | | acetate | | | | | |
| Example | R-21 | PGMEA | 146 | gamma- | 204 | PGME | 121 | 50/30/20 | 20 | 16.5 | |
| 21 | | | | Butyrolactone | | | | | | | |
| Example | R-22 | PGMEA | 146 | gamma- | 204 | PGME | 121 | 79/1/20 | 1 | 16.1 | |
| 22 | | | | Butyrolactone | | | | | | | |
| | | Composition | | | | | | | | | |
| | | Resin (A) | | Photoacid generator (C) | | Acid diffusion control | | | | Surfactant | |
| | | | Content | | Content | agent (D) | | Hydrophobic resin | | | Content |
| | Com- | | [mass | | [mass | | Content | | Content | | [mass |
| | position | Type | %] | Type | %] | Type | [mass %] | Type | [mass %] | Type | %] |
| Comparative | RX-1 | P-A | 92.410 | PAG-A | 7.10 | Q-A/Q-E | 0.245/0.160 | — | — | W-A | 0.085 |
| Example 1 | | | | | | | | | | | |
| Comparative | RX-2 | P-A | 92.410 | PAG-A | 7.10 | Q-A/Q-E | 0.245/0.160 | — | — | W-A | 0.085 |
| Example 2 | | | | | | | | | | | |
| Comparative | RX-3 | P-A | 92.410 | PAG-A | 7.10 | Q-A/Q-E | 0.245/0.160 | — | — | W-A | 0.085 |
| Example 3 | | | | | | | | | | | |
| Comparative | RX-4 | P-B | 91.713 | PAG-A | 7.80 | Q-A/Q-E | 0.250/0.152 | — | — | W-A | 0.085 |
| Example 4 | | | | | | | | | | | |
| Comparative | RX-5 | P-A | 92.200 | PAG-A | 7.30 | Q-B/Q-E | 0.260/0.155 | — | — | W-A | 0.085 |
| Example 5 | | | | | | | | | | | |
| Comparative | RX-6 | P-A | 92.035 | PAG-A | 7.50 | Q-A/Q-E | 0.250/0.130 | — | — | W-A | 0.085 |
| Example 6 | | | | | | | | | | | |
| Comparative | RX-7 | P-B | 92.655 | PAG-A | 6.90 | Q-A | 0.240 | F-A | 0.120 | W-A | 0.085 |
| Example 7 | | | | | | | | | | | |
| Comparative | RX-8 | P-A | 92.308 | PAG-A | 7.20 | Q-A/Q-E | 0.250/0.157 | — | — | W-A | 0.085 |
| Example 8 | | | | | | | | | | | |

| | | Composition | | | | | | | | |
|---|---|---|---|---|---|---|---|---|---|---|
| | | | | | | | | Solvent | Solvent | |
| | | Solvent 1 | | Solvent 2 | | Solvent 3 | | ratio | 2/Photo- | |
| | | | Boiling | | Boiling | | Boiling | Solvent 1/ | acid | Solid |
| | Com- | | point | | point | | point | Solvent 2/ | generator | content |
| | position | Type | (° C.) | Type | (° C.) | Type | (° C.) | Solvent 3 | (C) | [mass %] |
| Comparative | RX-1 | PGMEA | 146 | — | — | PGME | 121 | 80/0/20 | 0 | 15.8 |
| Example 1 | | | | | | | | | | |
| Comparative | RX-2 | PGMEA | 146 | Ethyl lactate | 154 | — | — | 80/20/0 | 0 | 15.8 |
| Example 2 | | | | | | | | | | |
| Comparative | RX-3 | PGMEA | 146 | 1,4-Dioxane | 104 | — | — | 80/20/0 | 0 | 15.8 |
| Example 3 | | | | | | | | | | |
| Comparative | RX-4 | PGMEA | 146 | Dibutyl ether | 142 | — | — | 80/20/0 | 0 | 15.8 |
| Example 4 | | | | | | | | | | |
| Comparative | RX-5 | PGMEA | 146 | gamma- | 204 | PGME | 121 | 30/50/20 | 37 | 15.5 |
| Example 5 | | | | Butyrolactone | | | | | | |
| Comparative | RX-6 | PGMEA | 146 | gamma- | 204 | PGME | 121 | 79.5/ | 0.4 | 15.7 |
| Example 6 | | | | Butyrolactone | | | | 0.5/20 | | |
| Comparative | RX-7 | PGMEA | 146 | gamma- | 204 | PGME | 121 | 62/33/5 | 26 | 15.6 |
| Example 7 | | | | Butyrolactone | | | | | | |
| Comparative | RX-8 | PGMEA | 146 | Tetraethylene | 275 | PGME | 121 | 70/10/20 | 0 | 16.9 |
| Example 8 | | | | glycol | | | | | | |

### Formation of Pattern

A spin coater ACT-8 manufactured by Tokyo Electron Ltd. was used to apply the resist composition prepared as described above onto a hexamethyldisilazane-treated Si substrate (manufactured by Advanced Materials Technology, Inc.) without providing an antireflection layer, and drying was performed by heating at 120° C. for 60 seconds to form an actinic ray-sensitive or radiation-sensitive film (resist film). The film thickness of the resist film was the thickness shown in Table 4 below. The resist film was subjected to pattern exposure using a KrF excimer laser scanner (manufactured by ASML, PAS5500/850C, wavelength: 248 nm) under exposure conditions of NA=0.55 and σ=0.60. After the irradiation, baking was performed at 140° C. for 60 seconds, immersion using a 2.38 mass % aqueous solution of tetramethylammonium hydroxide (TMAH) for 60 seconds was performed, and rinsing with water for 30 seconds and drying were then performed.

The exposure was performed through a mask having a line-and-space pattern that could provide a space pattern of 210 nm and a pitch of 500 nm after reduced projection exposure. An exposure dose that could form a space pattern of 180 nm and a pitch of 500 nm was defined as an optimum exposure dose, and this optimum exposure dose was defined as a sensitivity (mJ/cm²). The space pattern width was measured using a scanning electron microscope (SEM) (9380 manufactured by Hitachi, Ltd.).

### Average Film Thickness

After the above-described resist film was formed on the Si substrate, the film thickness was measured at 300 points concentrically from a central portion of the wafer using VM-3110 manufactured by SCREEN Co., Ltd., and the average value thereof was defined as the average film thickness of the resist film shown in Table 4 below.

### Evaluation of Exposure Latitude (EL)

In the wafer having an isolated space pattern formed at the above sensitivity, a value (percentage) obtained by dividing an exposure dose at which the line width changed by 10% by an effective exposure dose was defined as the exposure latitude. The larger the value, the smaller a change in performance due to a change in exposure dose, and the better the exposure latitude.

### Evaluation of Residual Solvent in Resist Film

Extraction of Resist Film into Organic Solvent

A spin coater ACT-8 manufactured by Tokyo Electron Ltd. was used to apply the resist composition prepared as described above onto a hexamethyldisilazane-treated Si substrate (manufactured by Advanced Materials Technology, Inc.) without providing an antireflection layer, and drying was performed by heating at 120° C. for 60 seconds to form a resist film. Subsequently, the wafer was immersed in methanol serving as a solvent to dissolve the resist film into the solvent. The film thickness of the resist film was the thickness shown in Table 4 below.

The weight of the wafer was measured before and after the extraction, and the difference was defined as the mass of the extracted resist film.

### Preparation of Calibration Curve

A solvent included in the resist composition was used as a standard, and a predetermined amount of the solvent was added to a methanol solution, followed by measurement by gas chromatography. The measured peak area and the addition amount were used to prepare a calibration curve.

### Measurement of Amount of Residual Solvent in Resist Film

The methanol solution in which the resist film was dissolved was measured by gas chromatography, and the peak area was calculated for each solvent included in the resist composition. The calculated peak area was compared with the calibration curve, and the amount of the residual solvent was determined by calculation.

The calculation formula used is as follows.

Amount of residual solvent (mass %)=(amount of solvent in extracted resist film determined from calibration curve)/(mass of extracted resist film)×100

The resist compositions used and the results are shown in Table 4 below.

TABLE 4

| | | Average film | | Amount of residual |
|---|---|---|---|---|
| | | thickness | EL | solvent in film |
| | Composition | [nm] | [%] | [mass %] |
| Example 1 | R-1 | 1,520 | 22 | 4 |
| Example 2 | R-2 | 1,530 | 21 | 5 |
| Example 3 | R-3 | 1,510 | 14 | 10 |
| Example 4 | R-4 | 1,500 | 14 | 11 |
| Example 5 | R-5 | 1,520 | 15 | 10 |
| Example 6 | R-6 | 1,495 | 14 | 12 |
| Example 7 | R-7 | 1,531 | 19 | 8 |
| Example 8 | R-8 | 1,530 | 19 | 6 |
| Example 9 | R-9 | 1,535 | 18 | 6 |
| Example 10 | R-10 | 1,532 | 10 | 10 |
| Example 11 | R-11 | 1,540 | 18 | 8 |
| Example 12 | R-12 | 1,520 | 15 | 10 |
| Example 13 | R-13 | 1,525 | 16 | 11 |
| Example 14 | R-14 | 1,510 | 14 | 14 |
| Example 15 | R-15 | 1,535 | 15 | 15 |
| Example 16 | R-16 | 1,555 | 18 | 8 |
| Example 17 | R-17 | 1,545 | 19 | 8 |
| Example 18 | R-18 | 1,525 | 19 | 6 |
| Example 19 | R-19 | 1,515 | 19 | 6 |
| Example 20 | R-20 | 1,530 | 20 | 5 |
| Example 21 | R-21 | 1,515 | 17 | 9 |
| Example 22 | R-22 | 1,520 | 11 | 16 |
| Comparative | RX-1 | 1,525 | 8 | 20 |
| Example 1 | | | | |
| Comparative | RX-2 | 1,525 | 7 | 18 |
| Example 2 | | | | |
| Comparative | RX-3 | 1,530 | 6 | 22 |
| Example 3 | | | | |
| Comparative | RX-4 | 1,530 | 6 | 21 |
| Example 4 | | | | |
| Comparative | RX-5 | 1,515 | 5 | 24 |
| Example 5 | | | | |
| Comparative | RX-6 | 1,520 | 7 | 21 |
| Example 6 | | | | |
| Comparative | RX-7 | 1,525 | 4 | 26 |
| Example 7 | | | | |
| Comparative | RX-8 | 1,530 | 5 | 25 |
| Example 8 | | | | |

As can be seen from Table 4, the resist compositions of Examples had a small amount of residual solvent in the resist film and had a good EL performance.

### Vinyl Group-Containing Compound (G)

The following G-1 to G-4 were used as the vinyl group-containing compound.

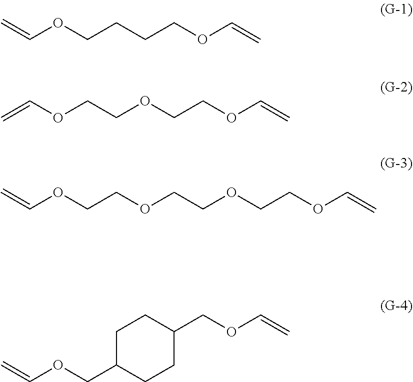

### Preparation of Resist Composition

Resist compositions R-23 to R-30 and RX-9 to RX-11 were each obtained by dissolving the components shown in Table 5 below in the solvents shown in Table 5 to prepare a solution having the concentration of solid contents shown in Table 5, and filtering the solution through a polyethylene filter having a pore size of 3 m.

The solid content means all components other than the solvents. The obtained resist compositions were used in Examples and Comparative Examples.

The content of each component in Table 5 is a ratio based on mass relative to the total solid content of each resist composition. The “%” is based on the mass (that is, “mass %”). The concentration of solid contents means a mass percentage of the mass of other components excluding the solvents relative to the total mass of each resist composition.

As the solvent (S), the compounds shown in Table 5 were used at the mass ratios shown in Table 5.

In Examples 23 to 30 and Comparative Examples 9 and 11, two compounds were used as the acid diffusion control agent (D) at the “mass %” shown in Table 5.

Table 5 also shows the mass ratio of the solvent SB to the photoacid generator (C) (solvent SB/photoacid generator (C)).

TABLE 5

| | | Composition | | | | | | | | | | | |
|---|---|---|---|---|---|---|---|---|---|---|---|---|---|
| | | | | | | | | | | | | Vinyl group- | |
| | | | | Photoacid | | Acid diffusion | | Hydrophobic | | | | containing | |
| | | Resin (A) | | generator (C) | | control agent (D) | | resin | | Surfactant | | compound | |
| | | | Con- | | Con- | | Con- | | Con- | | Con- | | Con- |
| | Com- | | tent | | tent | | tent | | tent | | tent | | tent |
| | posi- | | [mass | | [mass | | [mass | | [mass | | [mass | | [mass |
| | tion | Type | %] | Type | %] | Type | %] | Type | %] | Type | %] | Type | %] |
| Example 23 | R-23 | P-A | 87.320 | PAG-A | 7.20 | Q-A/Q-E | 0.235/0.160 | — | — | W-A | 0.085 | G-1 | 5.0 |
| Example 24 | R-24 | P-A | 86.751 | PAG-A | 7.26 | Q-A/Q-E | 0.247/0.157 | — | — | W-A | 0.085 | G-4 | 5.5 |
| Example 25 | R-25 | P-A | 86.993 | PAG-A | 7.50 | Q-A/Q-E | 0.269/0.153 | — | — | W-A | 0.085 | G-2 | 5.0 |
| Example 26 | R-26 | P-A | 85.605 | PAG-A | 7.90 | Q-A/Q-E | 0.259/0.151 | — | — | W-A | 0.085 | G-3 | 6.0 |
| Example 27 | R-27 | P-A | 85.533 | PAG-A | 7.46 | Q-C/Q-E | 0.269/0.153 | — | — | W-C | 0.085 | G-2 | 6.5 |
| Example 28 | R-28 | P-B | 86.143 | PAG-B | 7.35 | Q-D/Q-E | 0.269/0.153 | — | — | W-C | 0.085 | G-2 | 6.0 |
| Example 29 | R-29 | P-E | 92.011 | PAG-A | 7.50 | Q-A/Q-E | 0.247/0.157 | — | — | W-A | 0.085 | — | — |
| Example 30 | R-30 | P-E | 92.261 | PAG-A | 7.25 | Q-A/Q-E | 0.247/0.157 | — | — | W-A | 0.085 | — | — |
| Com- | RX-9 | P-A | 86.700 | PAG-A | 7.30 | Q-B/Q-E | 0.260/0.155 | — | — | W-A | 0.085 | G-2 | 5.5 |
| parative | | | | | | | | | | | | | |
| Example 9 | | | | | | | | | | | | | |
| Com- | RX-10 | P-B | 87.655 | PAG-A | 6.90 | Q-A | 0.240 | F-A | 0.120 | W-A | 0.085 | G-2 | 5.0 |
| parative | | | | | | | | | | | | | |
| Example 10 | | | | | | | | | | | | | |
| Com- | RX-11 | P-A | 86.808 | PAG-A | 7.20 | Q-A/Q-E | 0.250/0.157 | — | — | W-A | 0.085 | G-2 | 5.5 |
| parative | | | | | | | | | | | | | |
| Example 11 | | | | | | | | | | | | | |

| | | Composition | | | | | | | | |
|---|---|---|---|---|---|---|---|---|---|---|
| | | Solvent | | Solvent | | Solvent | | | Solvent | |
| | | SA | | SB | | SC | | Solvent | SB/ | |
| | Com- | | Boiling | | Boiling | | Boiling | ratio | Photoacid | Solid |
| | posi- | | point | | point | | point | SA/SB/ | generator | content |
| | tion | Type | (° C.) | Type | (° C.) | Type | (° C.) | SC | (C) | [mass %] |
| Example 23 | R-23 | PGMEA | 146 | gamma- | 204 | — | — | 80/20/0 | 15 | 35.8 |
| | | | | Butyrolactone | | | | | | |
| Example 24 | R-24 | PGMEA | 146 | gamma- | 204 | PGME | 121 | 70/10/20 | 7 | 36.1 |
| | | | | Butyrolactone | | | | | | |
| Example 25 | R-25 | PGMEA | 146 | Ethylene | 188 | PGME | 121 | 70/10/20 | 7 | 35.9 |
| | | | | glycol | | | | | | |
| | | | | monobutyl | | | | | | |
| | | | | ether acetate | | | | | | |
| Example 26 | R-26 | PGMEA | 146 | Ethyl 3- | 170 | PGME | 121 | 70/10/20 | 7 | 35.8 |
| | | | | ethoxy- | | | | | | |
| | | | | propionate | | | | | | |
| Example 27 | R-27 | PGMEA | 146 | gamma- | 204 | PGME | 121 | 70/10/20 | 7 | 35.9 |
| | | | | Butyrolactone | | | | | | |
| Example 28 | R-28 | PGMEA | 146 | gamma- | 204 | PGME | 121 | 65/15/20 | 11 | 35.9 |
| | | | | Butyrolactone | | | | | | |
| Example 29 | R-29 | PGMEA | 146 | gamma- | 204 | PGME | 121 | 70/10/20 | 7 | 36.2 |
| | | | | Butyrolactone | | | | | | |
| Example 30 | R-30 | PGMEA | 146 | gamma- | 204 | — | — | 70/10/20 | 15 | 35.9 |
| | | | | Butyrolactone | | | | | | |
| | | Composition | | | | | | | | |
| | | | | | | | | Solvent | Solvent | |
| | | Solvent 1 | | Solvent 2 | | Solvent 3 | | ratio | 2/ | |
| | Com- | | Boiling | | Boiling | | Boiling | Solvent 1/ | Photoacid | Solid |
| | posi- | | point | | point | | point | Solvent 2/ | generator | content |
| | Com- | Type | (° C.) | Type | (° C.) | Type | (° C.) | Solvent 3 | (C) | [mass %] |
| Com- | RX-9 | PGMEA | 146 | gamma- | 204 | PGME | 121 | 30/50/20 | 37 | 35.5 |
| parative | | | | Butyrolactone | | | | | | |
| Example 9 | | | | | | | | | | |
| Com- | RX-10 | PGMEA | 146 | gamma- | 204 | PGME | 121 | 62/33/5 | 26 | 35.6 |
| parative | | | | Butyrolactone | | | | | | |
| Example 10 | | | | | | | | | | |
| Com- | RX-11 | PGMEA | 146 | Tetraethylene | 275 | PGME | 121 | 70/10/20 | 8 | 36.9 |
| parative | | | | glycol | | | | | | |
| Example 11 | | | | | | | | | | |

The resin (P-E) in Table 5 is the following resin.

Acetal-based resin protected with monofunctional and polyfunctional vinyl ethers

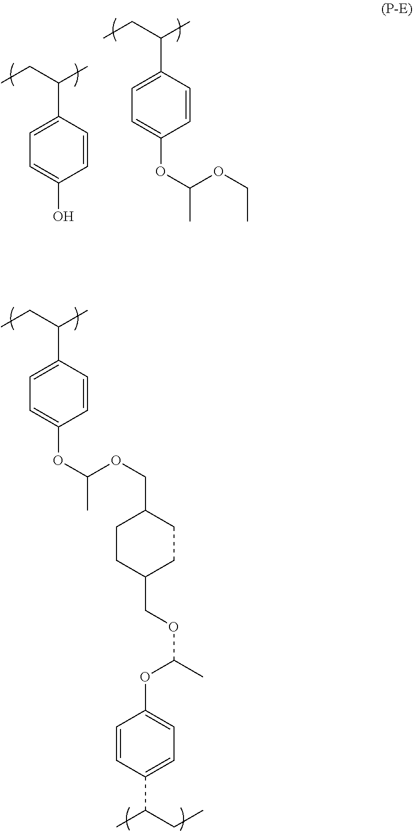

### Formation of Pattern

A spin coater “ACT-8” manufactured by Tokyo Electron Ltd. was used to apply the prepared resist composition onto a hexamethyldisilazane-treated Si substrate (manufactured by Advanced Materials Technology, Inc.) without providing an antireflection layer, and drying was performed by heating at 130° C. for 180 seconds to form an actinic ray-sensitive or radiation-sensitive film (resist film). The film thickness of the resist film was the thickness shown in Table 6 below. The resist film was subjected to pattern exposure using a KrF excimer laser scanner (manufactured by ASML, PAS5500/850C, wavelength: 248 nm) through the following mask and at the following optimum exposure dose under exposure conditions of NA (numerical aperture)=0.68 and σ=0.60. After the irradiation, baking was performed at 130° C. for 60 seconds, immersion using a 2.38 mass % aqueous solution of tetramethylammonium hydroxide (TMAH) for 60 seconds was performed, and rinsing with water for 30 seconds and drying were then performed.

The exposure was performed through a mask having a line-and-space pattern that could provide a space pattern of 3 m and a pitch of 33 m after reduced projection exposure. An exposure dose that could form a space pattern of 3 m and a pitch of 33 m was defined as an optimum exposure dose (sensitivity) (mJ/cm²). The space pattern width was measured using a scanning electron microscope (SEM) (9380I manufactured by Hitachi, Ltd.).

Through the above procedure, a pattern wafer for evaluation, the pattern wafer having a substrate and a pattern (resist pattern) formed on a surface of the substrate, was obtained.

### Average Film Thickness

After the above-described resist film was formed on the Si substrate, the film thickness was measured at 300 points concentrically from a central portion of the wafer using VM-3110 manufactured by SCREEN Co., Ltd., and the average value thereof was defined as the average film thickness of the resist film shown in Table 6 below.

### Evaluation of Exposure Latitude (EL)

In the wafer having an isolated space pattern formed at the above sensitivity, a value (percentage) obtained by dividing an exposure dose at which the line width changed by 10% by an effective exposure dose was defined as the exposure latitude. The larger the value, the smaller a change in performance due to a change in exposure dose, and the better the exposure latitude.

### Evaluation of Residual Solvent in Resist Film

Extraction of Resist Film into Organic Solvent

A spin coater ACT-8 manufactured by Tokyo Electron Ltd. was used to apply the resist composition prepared as described above onto a hexamethyldisilazane-treated Si substrate (manufactured by Advanced Materials Technology, Inc.) without providing an antireflection layer, and drying was performed by heating at 130° C. for 180 seconds to form a resist film. Subsequently, the wafer was immersed in methanol serving as a solvent to dissolve the resist film into the solvent. The film thickness of the resist film was the thickness shown in Table 6 below.

The weight of the wafer was measured before and after the extraction, and the difference was defined as the mass of the extracted resist film.

### Preparation of Calibration Curve

A solvent included in the resist composition was used as a standard, and a predetermined amount of the solvent was added to a methanol solution, followed by measurement by gas chromatography. The measured peak area and the addition amount were used to prepare a calibration curve.

### Measurement of Amount of Residual Solvent in Resist Film

The methanol solution in which the resist film was dissolved was measured by gas chromatography, and the peak area was calculated for each solvent included in the resist composition. The calculated peak area was compared with the calibration curve, and the amount of the residual solvent was determined by calculation.

The calculation formula used is as follows.

Amount of residual solvent (mass %)=(amount of solvent in extracted resist film determined from calibration curve)/(mass of extracted resist film)×100

In addition, the crack resistance was also evaluated as follows.

### Evaluation of Crack Resistance

The pattern wafer for evaluation was subjected to vacuum treatment (evacuation) for 60 seconds in a chamber in a critical dimension-scanning electron microscope (CD-SEM). The pressure of the inside of the chamber was set to 0.002 Pa.

After the vacuum treatment, the pattern wafer for evaluation was observed with an optical microscope to evaluate the occurrence or nonoccurrence of cracking. Specifically, cracks of the pattern formed on the surface of the substrate were checked and evaluated on the basis of the following criteria.
A: No cracks
B: less than 20 cracks
C: 20 or more cracks

The resist compositions used and the results are shown in Table 6 below.

TABLE 6

| | | Average film | Amount of residual | Crack |
|---|---|---|---|---|
| | Composi- | thickness | solvent in film | resistance |
| | tion | [nm] | [mass %] | evaluation |
| Example 23 | R-23 | 10,200 | 6 | A |
| Example 24 | R-24 | 10,500 | 8 | A |
| Example 25 | R-25 | 10,100 | 15 | A |
| Example 26 | R-26 | 10,300 | 17 | A |
| Example 27 | R-27 | 10,100 | 21 | B |
| Example 28 | R-28 | 10,050 | 23 | B |
| Example 29 | R-29 | 10,800 | 20 | B |
| Example 30 | R-30 | 10,200 | 22 | B |
| Comparative | RX-9 | 10,100 | 36 | C |
| Example 9 | | | | |
| Comparative | RX-10 | 10,120 | 39 | C |
| Example 10 | | | | |
| Comparative | RX-11 | 10,100 | 38 | C |
| Example 11 | | | | |

As can be seen from Table 6, the resist compositions of Examples had a small amount of residual solvent in the resist film, had a good EL performance, and further had good crack resistance.

What is claimed is:

1. An actinic ray-sensitive or radiation-sensitive resin composition comprising:
a resin (A) undergoing an increase in alkali solubility due to action of acid;
a compound (C) generating acid upon irradiation with an actinic ray or radiation; and
a solvent (S) including a solvent SA having a boiling point of 130° C. to 150° C. and a solvent SB having a boiling point of 155° C. to 250° C.,
wherein a content of the solvent SA is higher than a content of the solvent SB, the content of the solvent SB relative to the whole solvent is 1% to 30% by mass, and
a concentration of solid contents is 10% by mass or more.

2. The actinic ray-sensitive or radiation-sensitive resin composition according to claim 1, wherein the resin (A) is a resin containing a repeating unit having an acid-decomposable group and a repeating unit having a phenolic hydroxy group.

3. The actinic ray-sensitive or radiation-sensitive resin composition according to claim 1, wherein the resin (A) is a resin containing a repeating unit represented by the following general formula (Ia), a repeating unit represented by the following general formula (IIa), and a repeating unit represented by the following general formula (IIIa): 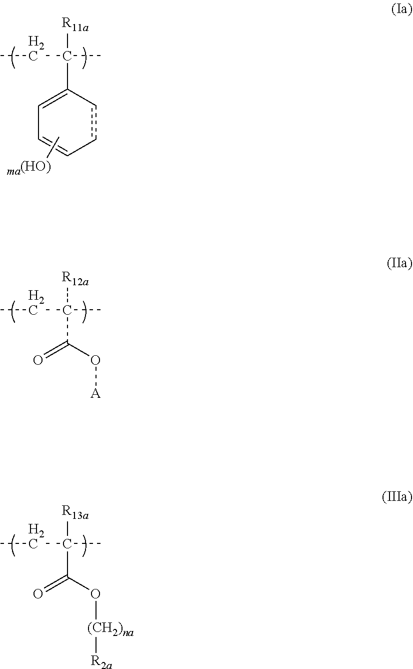
in the general formulae (Ia) to (IIIa),
A represents a group that leaves due to action of acid,
R₁₁ₐ to R₁₃ₐ each independently represent hydrogen or a methyl group,
R₂ₐ represents a cyclic group,
ma represents 1 or 2, and
na represents an integer of 0 to 2.

4. The actinic ray-sensitive or radiation-sensitive resin composition according to claim 1, wherein the solvent SB has a boiling point of 180° C. to 220° C.

5. The actinic ray-sensitive or radiation-sensitive resin composition according to claim 1, wherein the solvent SB includes at least one solvent selected from the group consisting of alcohol-based, glycol ether-based, and ester-based solvents.

6. The actinic ray-sensitive or radiation-sensitive resin composition according to claim 1, wherein the solvent SB includes at least one solvent selected from the group consisting of ethylene glycol, propylene glycol, gamma-butyrolactone, ethyl acetoacetate, dipropylene glycol monomethyl ether, ethylene glycol monobutyl ether acetate, and diethylene glycol diethyl ether.

7. The actinic ray-sensitive or radiation-sensitive resin composition according to claim 1, wherein the compound (C) generating acid upon irradiation with an actinic ray or radiation is included in an amount of 5% by mass or more relative to a total solid content in the actinic ray-sensitive or radiation-sensitive resin composition.

8. The actinic ray-sensitive or radiation-sensitive resin composition according to claim 1, wherein a mass ratio of the solvent SB to the compound (C) generating acid upon irradiation with an actinic ray or radiation (solvent SB/compound (C) generating acid upon irradiation with actinic ray or radiation) is 0.1 to 200.

9. The actinic ray-sensitive or radiation-sensitive resin composition according to claim 1, wherein the solvent (S) further includes a solvent SC having a boiling point of 50° C. to 129° C.

10. The actinic ray-sensitive or radiation-sensitive resin composition according to claim 1, the composition further comprising a vinyl group-containing compound.

11. An actinic ray-sensitive or radiation-sensitive film formed from the actinic ray-sensitive or radiation-sensitive resin composition according to claim 1.

12. A pattern forming method comprising:
forming an actinic ray-sensitive or radiation-sensitive film using the actinic ray-sensitive or radiation-sensitive resin composition according to claim 1 on a substrate;
exposing the actinic ray-sensitive or radiation-sensitive film to obtain an exposed actinic ray-sensitive or radiation-sensitive film; and
developing the exposed actinic ray-sensitive or radiation-sensitive film using a developer to form a pattern.

13. The pattern forming method according to claim 12, wherein a light source for the exposing is KrF.

14. The pattern forming method according to claim 12, wherein the actinic ray-sensitive or radiation-sensitive film formed on the substrate has a film thickness of 500 nm or more.

15. A method for producing an electronic device, the method comprising the pattern forming method according to claim 12.

16. The actinic ray-sensitive or radiation-sensitive resin composition according to claim 2, wherein the resin (A) is a resin containing a repeating unit represented by the following general formula (Ia), a repeating unit represented by the following general formula (IIa), and a repeating unit represented by the following general formula (IIIa): 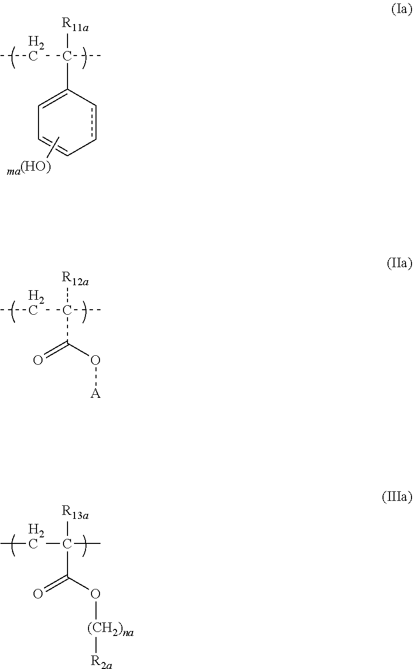
in the general formulae (Ia) to (IIIa),
A represents a group that leaves due to action of acid,
R₁₁ₐ to R₁₃ₐ each independently represent hydrogen or a methyl group,
R₂ₐ represents a cyclic group,
ma represents 1 or 2, and
na represents an integer of 0 to 2.

17. The actinic ray-sensitive or radiation-sensitive resin composition according to claim 2, wherein the solvent SB has a boiling point of 180° C. to 220° C.

18. The actinic ray-sensitive or radiation-sensitive resin composition according to claim 3, wherein the solvent SB has a boiling point of 180° C. to 220° C.
